(19) United States
(12) Patent Application Publication
(10) Pub. No.: US 2026/0314478 A1
(43) Pub. Date: Oct. 8, 2026

(54) SEMICONDUCTOR DEVICE WITH REDUCED WARPAGE

(71) Applicant: SAMSUNG ELECTRONICS CO., LTD., Suwon-si (KR)

(72) Inventors: Gyuseong PARK, Suwon-si (KR); Joongwon SHIN, Suwon-si (KR); Dae-Gwon HA, Suwon-si (KR)

(73) Assignee: SAMSUNG ELECTRONICS CO., LTD., Suwon-si (KR)

(21) Appl. No.: 19/382,712

(22) Filed: Nov. 7, 2025

(30) Foreign Application Priority Data
Apr. 7, 2025 (KR) 10-2025-0044470

(51) Int. Cl. H10W 74/10; H10W 20/20; H10W 74/01; H10W 90/00; H10W 74/15; H10W 90/20; H10W 90/26

(52) U.S. Cl. CPC H10W 74/147; H10W 20/20; H10W 74/01; H10W 90/00; H10W 74/15; H10W 90/26; H10W 90/297; H10W 90/722; H10W 90/724; H10W 90/732; H10W 90/734

(57) ABSTRACT

A semiconductor device includes: a substrate; a first via penetration the substrate; a second via penetrating the substrate; and an insulating pattern surrounding the first via and the second via, in which the insulating pattern comprises a first portion between the first via and the second via, the first portion comprises a first pattern portion and a second pattern portion overlapping the first pattern portion, and a width of the first pattern portion is smaller than a width of the second pattern portion.

### CROSS-REFERENCE TO RELATED APPLICATIONS

This U.S. non-provisional patent application is based on and claims priority under 35 U.S.C. § 119 of Korean Patent Application No. 10-2025-0044470, filed on Apr. 7, 2025, the disclosure of which is incorporated herein in its entirety by reference.

### BACKGROUND

The present disclosure herein relates to a semiconductor device, and more particularly, to a semiconductor device including an insulating layer surrounding a via and an insulating pattern on the insulating layer.

A semiconductor device is attracting attention as an important component in the electronics industry due to characteristics thereof such as miniaturization, multi-functionality, and/or low manufacturing cost. The semiconductor device may be classified into a semiconductor memory device that stores a logic data, a semiconductor logic device that calculates and processes the logic data, and a hybrid semiconductor device that includes a memory component and a logic component.

Recently, with a high speed and low power consumption of an electronic apparatus, a high operation speed, a low operation voltage and/or the like are/is also required for the semiconductor device built therein. In order to satisfy such requirements, a more highly-integrated semiconductor device is needed. However, when the semiconductor device becomes more highly-integrated, electrical characteristics and production yield of the semiconductor device may be reduced. For example, the higher integration of components leads to a warpage phenomenon, thereby reducing stability of the of the semiconductor device. Accordingly, much research for improving the electrical characteristics and the production yield of the semiconductor device is being carried out.

### SUMMARY

Some embodiments of the present disclosure concept provide a semiconductor device with improved electrical characteristics and reliability.

According to some embodiments, a semiconductor device including: a substrate; a first via penetrating the substrate; a second via penetrating the substrate; and an insulating pattern surrounding the first via and the second via, in which the insulating pattern comprises a first portion between the first via and the second via, the first portion comprises a first pattern portion and a second pattern portion overlapping the first pattern portion, and a width of the first pattern portion is smaller than a width of the second pattern portion.

According to some embodiments, a semiconductor device includes: a substrate; a first via penetrating the substrate; a second via penetrating the substrate; and an insulating pattern surrounding the first via and the second via, in which the insulating pattern comprises a first portion between the first via and the second via, the first portion comprises a first pattern portion and a second pattern portion overlapping the first pattern portion, the second pattern portion comprises a first part, a second part and a third part, the second part of the second pattern portion overlaps the first pattern portion, the first part and the third part of the second pattern portion are spaced apart from each other, the second part of the second pattern portion is between the first part and the third part, and a level of a surface of the first pattern portion is lower than a level of a surface of the first part of the second pattern portion and a level of a surface of the third part of the second pattern portion.

According to some embodiments, a semiconductor device includes: a substrate; a first via penetrating the substrate; a second via penetrating the substrate; an insulating pattern on a surface of the substrate, and surrounding the first via; and an insulating layer on the substrate, in which the insulating pattern comprises a first portion between the first via and the second via, the first portion comprises a first pattern portion and a second pattern portion overlapping the first pattern portion, and the first pattern portion protrudes from the second pattern portion.

According to some embodiments of the present disclosure, a method for manufacturing a semiconductor device includes forming a first via and a second via which penetrate a substrate, a top surface of the substrate including a first part spaced apart from the first via and the second via, and a second part in contact with the first via, and forming an insulating pattern in contact with the first part of the substrate, and spaced apart from the second part of the substrate, wherein the forming of the insulating pattern includes forming an insulating layer in contact with the first part and the second part of the substrate, exposing the first part of the top surface of the substrate by partially removing the insulating layer, and forming an insulating pattern in contact with the insulating layer and the first part of the top surface of the substrate, and the insulating pattern includes a different insulating material from the insulating layer.

According to some embodiments, the semiconductor device includes an insulating layer surrounding the first via and the second via, in which the first portion is spaced apart from the first via and the second via, and the insulating layer includes a first part between the first pattern portion and the first via, and a second part between the second pattern portion and the first via.

According to some embodiments, the insulating pattern and the insulating layer include different insulating materials.

According to some embodiments, a surface of the second pattern portion is connected to a wall of the first pattern portion and a wall of the second pattern portion.

According to some embodiments, the insulating layer is in contact with a surface of the substrate, a wall of the first via, a wall of the first pattern portion and a wall of the second pattern portion.

According to some embodiments, a surface of the second pattern portion and a surface of the insulating layer are coplanar with each other.

According to some embodiments, the insulating layer is in contact with a surface of the second pattern portion.

According to some embodiments, the first via, the second via, and the first portion are spaced apart from each other in a first direction, the semiconductor device further includes a third via spaced apart from the first via and the second via in a second direction crossing the first direction, the insulating pattern further includes a planarization portion between the first via and the third via, the planarization portion is spaced apart from the substrate, and the first portion is in contact with the substrate.

According to some embodiments, a first surface and a second surface of the planarization portion are flat.

According to some embodiments, the first pattern portion penetrates a surface of the substrate, and a surface of the first pattern portion is spaced apart from the surface of the substrate.

### BRIEF DESCRIPTION OF DRAWINGS

The accompanying drawings are included to provide a further understanding of the present disclosure, and are incorporated in and constitute a part of this specification. The drawings illustrate embodiments of the present disclosure and, together with the description, serve to explain principles of the present disclosure. In the drawings:

FIG. 1A is a plan view of a semiconductor device, according to some embodiments;

FIG. 1B is a cross-sectional view taken along line A-A’ of FIG. 1A, according to some embodiments;

FIG. 1C is an enlarged view of region A of FIG. 1A, according to some embodiments;

FIG. 1D is a cross-sectional view taken along line II-II’ of FIG. 1C, according to some embodiments;

FIG. 1E is a cross-sectional view taken along line III-III’ of FIG. 1C, according to some embodiments;

FIGS. 2A, 2B, 2C, 2D, 2E, 2F, 2G, 2H, 2I, 2J, 2K and 2L are diagrams describing a method for manufacturing a semiconductor device according to FIGS. 1A, 1B, 1C, 1D and 1E, according to some embodiments;

FIGS. 3A, 3B, 3C, 3D and 3E are diagrams illustrating a semiconductor device according to some embodiments;

FIGS. 4A, 4B and 4C are diagrams illustrating a semiconductor device according to some embodiments;

FIG. 5 is a diagram illustrating a semiconductor device according to some embodiments;

FIGS. 6A, 6B and 6C are diagrams illustrating a semiconductor device according to some embodiments;

FIGS. 7A, 7B, 7C, 7D, 7E, 7F, 7G and 7H are diagrams describing a method for manufacturing a semiconductor device according to FIGS. 6A, 6B and 6C, according to some embodiments;

FIG. 8 is a diagram illustrating a semiconductor device, according to some embodiments;

FIG. 9 is diagrams illustrating a semiconductor device, according to some embodiments;

FIG. 10 is diagrams illustrating a semiconductor device, according to some embodiments; and

FIG. 11 is diagrams illustrating a semiconductor device, according to some embodiments.

### DETAILED DESCRIPTION

Hereinafter, a semiconductor device and a method for manufacturing the same according to embodiments of the present disclosure will be described in detail with reference to the drawings.

It will be understood that, although the terms first, second, third, fourth, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the disclosure.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

A layer may be described as having an upper surface and a lower surface. As understood by one of ordinary skill in the art, the surfaces of a layer may also be described as first and second surfaces, where a first surface may be one of the upper surface and the lower surface of the layer, and the second surface may be the other of the upper surface and the lower surface of the layer.

The specification uses the terms of degree including “substantially” In one or more examples, when specifying that a parameter X may be substantially the same as parameter Y, the term “substantially” may be understood as X being within 10% of Y.

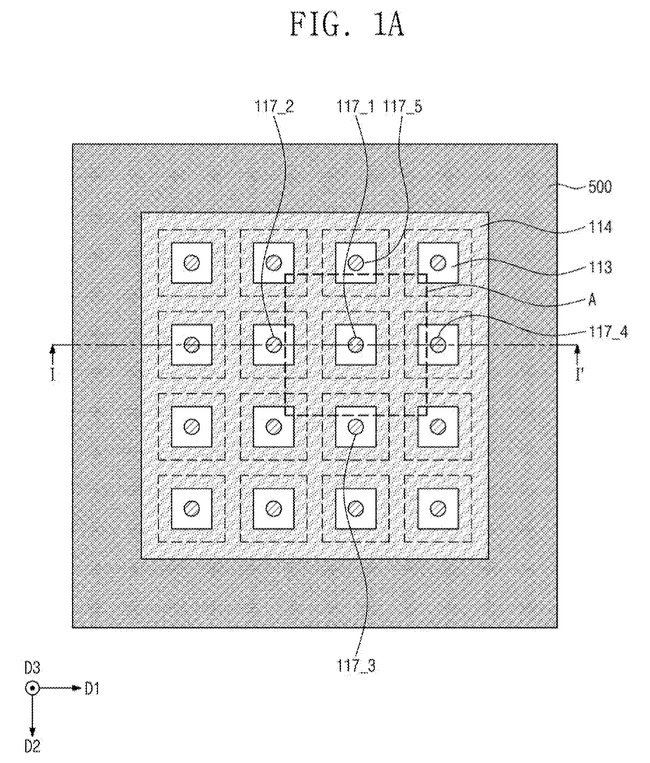

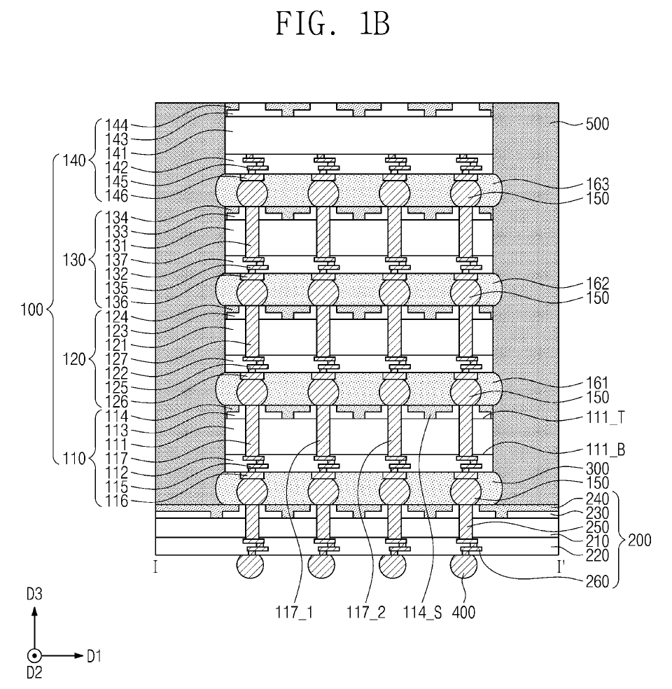

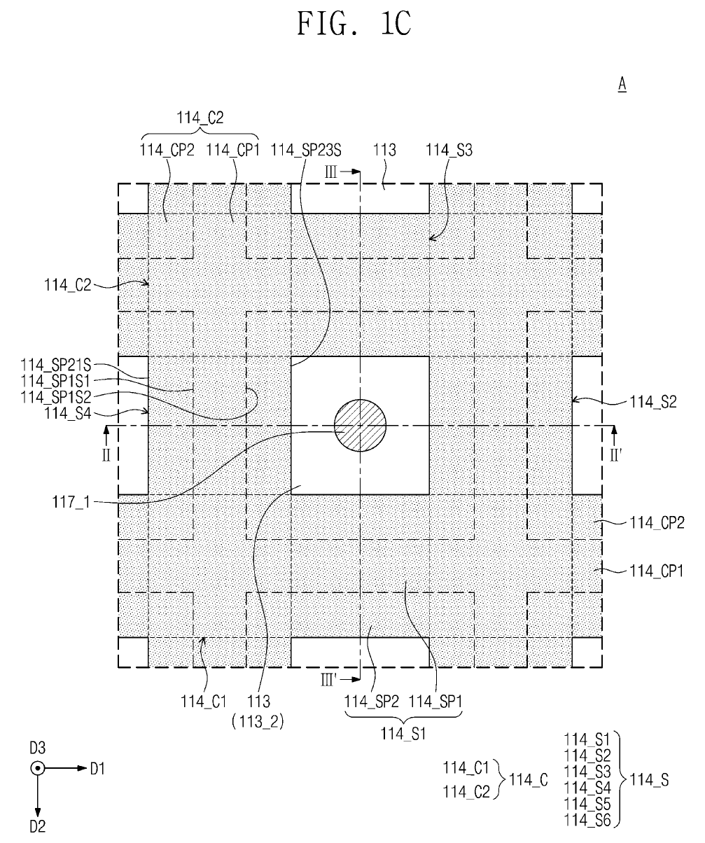

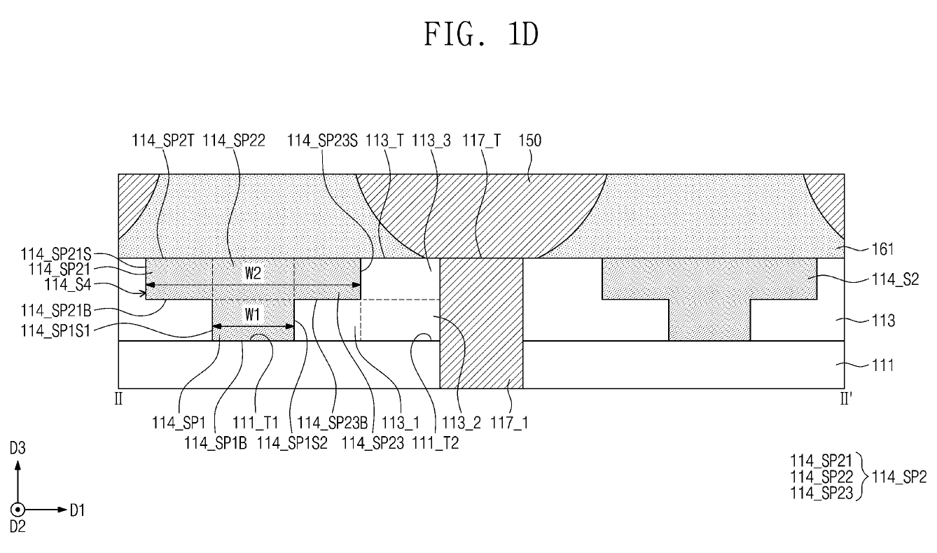

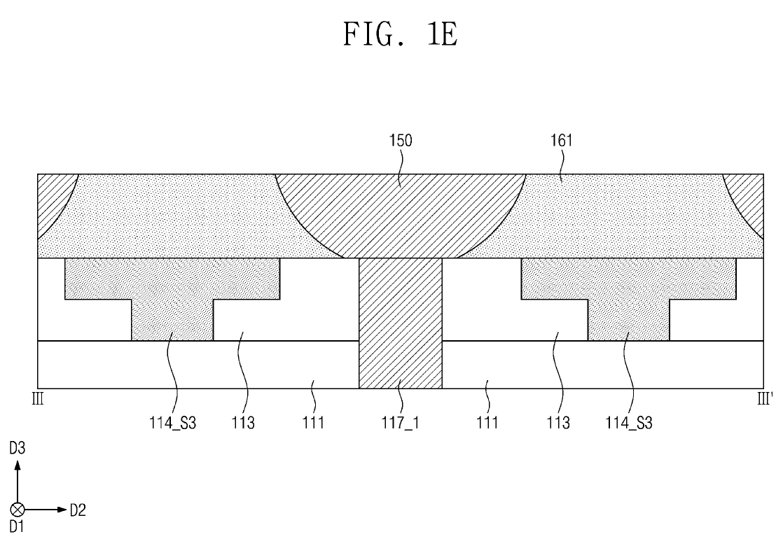

FIG. 1A is a plan view of a semiconductor device according to some embodiments. FIG. 1B is a cross-sectional view taken along line I-I’ of FIG. 1A. FIG. 1C is an enlarged view of region A of FIG. 1A. FIG. 1D is a cross-sectional view taken along line II-II’ of FIG. 1C. FIG. 1E is a cross-sectional view taken along line III-III’ of FIG. 1C.

Referring to FIGS. 1A and 1B, a stack structure 100, a base chip 200, a lower adhesive layer 300, a lower connection terminal 400 and a molding layer 500 may be included. The lower adhesive layer 300 and the molding layer 500 may include an insulating material. For example, the lower adhesive layer 300 and the molding layer 500 may include a polymer material. The lower connection terminal 400 may be disposed on a bottom surface of the base chip 200. The lower connection terminal 400 may include a conductive material. The lower connection terminal 400 may be electrically connected to the base chip 200.

According to some embodiments, the stack structure 100 may include a first semiconductor chip 110, a second semiconductor chip 120, a third semiconductor chip 130 and an upper semiconductor chip 140. The stack structure 100 may include interlayered connection terminals 150, a first interlayered adhesive layer 161, a second interlayered adhesive layer 162 and a third interlayered adhesive layer 163. The interlayered connection terminals 150 may be disposed on a top surface of the base chip 200 and upper surfaces of the first to third semiconductor chips 110, 120 and 130. The first interlayered adhesive layer 161, the second interlayered adhesive layer 162 or the third interlayered adhesive layer 163 may partially cover the interlayered connection terminals 150. In one or more examples, each of the adhesive layer 300 and interlayered adhesive layers 161, 162, and 163 may be formed of the same material. In one or more examples, at least one of the adhesive layer 300 and interlayered adhesive layers 161, 162, and 163 may be formed of a different material. In one or more examples, each of the adhesive layer 300 and interlayered adhesive layers 161, 162, and 163 may have a same size and/or shape. In one or more examples, at least one of the adhesive layer 300 and interlayered adhesive layers 161, 162, and 163 may have a different size and/or shape.

The interlayered connection terminal 150 may include a conductive material. The interlayered connection terminal 150 may electrically connect the first semiconductor chip 110 and the base chip 200. The interlayered connection terminal 150 may electrically connect the first semiconductor chip 110 and the second semiconductor chip 120. The interlayered connection terminal 150 may electrically connect the third semiconductor chip 130 and the second semiconductor chip 120. The interlayered connection terminal 150 may electrically connect the third semiconductor chip 130 and the upper semiconductor chip 140.

The first to third interlayered adhesive layers 161, 162 and 163 may include an insulating material. For example, the first to third interlayered adhesive layers 161, 162 and 163 may include a polymer material.

The stack structure 100 may include three or less semiconductor chips, or five or more semiconductor chips. The first to third semiconductor chips 110, 120 and 130 and the upper semiconductor chip 140 may be semiconductor chips including a memory integrated circuit. For example, the first to third semiconductor chips 110, 120 and 130 and the upper semiconductor chip 140 may be semiconductor chips including a DRAM.

The first semiconductor chip 110 may include a first substrate 111, a first lower insulating layer 112, a first upper insulating layer 113, a first insulating pattern 114, a first line structure 115, a first lower pad 116 and a penetration via 117.

The first substrate 111 may be a semiconductor substrate. For example, the first substrate 111 may include silicon, germanium, silicon-germanium, GaP or GaAs. According to some embodiments, the first substrate 111 may be a silicon-on-insulator (SOI) substrate or a germanium-on-insulator (GOI) substrate. The first substrate 111 may have a form of a plate extending along a plane extending in a first direction D1 and a second direction D2. The first direction D1 and the second direction D2 may cross each other. For example, the first direction D1 and the second direction D2 may be horizontal directions perpendicular to each other.

The first substrate 111 may include a top surface 111_T and a bottom surface 111_B. A circuit including a transistor, a diode, a capacitor, or the like may be formed on the bottom surface 111_B of the first substrate 111. The bottom surface 111_B of the first substrate 111 may be a front surface of the semiconductor substrate. Forming a circuit on the bottom surface 111_B of the first substrate 111 may include performing a front end of line (FEOL) process. The top surface 111_T of the first substrate 111 may be a rear surface opposed to the front surface on which the FEOL process is performed. As understood by one of ordinary skill in the art, a FEOL process includes an IC fabrication process where individual components (e.g., transistors, capacitors, resistors, etc.) are patterned in a semiconductor substrate.

The first lower insulating layer 112 may be disposed on the bottom surface 111_B of the first substrate 111. The first lower insulating film 112 may include an insulating material. For example, the first lower insulating layer 112 may include an oxide. The first line structure 115 may be disposed on the first lower insulating layer 112. The first lower insulating layer 112 may surround the first line structure 115. The first line structure 115 may include a conductive material. The first line structure 115 may include a plurality of lines, contacts or vias. The first lower pad 116 may be disposed on the first line structure 115. The first lower pad 116 may include a conductive material. The first lower pad 116 may electrically connect the first line structure 115 and the interlayered connection terminal 150.

The first upper insulating layer 113 may be disposed on the top surface 111_T of the first substrate 111. The first upper insulating layer 113 and the first insulating pattern 114 may cover the top surface 111_T of the first substrate 111. The first insulating pattern 114 may be disposed on the first upper insulating layer 113.

The first upper insulating layer 113 may include an insulating material. The first insulating pattern 114 may include an insulating material different from the first upper insulating layer 113. For example, the first upper insulating layer 113 may include an oxide, and the first insulating pattern 114 may include a nitride.

The penetration via 117 of the first semiconductor chip 110 may penetrate the first substrate 111. The penetration via 117 of the first semiconductor chip 110 may extend in a third direction D3. The penetration via 117 of the first semiconductor chip 110 may penetrate the top surface 111_T and the bottom surface 111_B of the first substrate 111. The penetration via 117 of the first semiconductor chip 110 may penetrate a bottom surface of the first upper insulating layer 113. The penetration via 117 of the first semiconductor chip 110 may include a first penetration via 117_1, a second penetration via 117_2, a third penetration via 117_3, a fourth penetration via 117_4 and a fifth penetration via 117_5. The second and fourth penetration vias 117_2 and 117_4 may be spaced apart from each other with the first penetration via 117_1 therebetween in the first direction D1. The third and fifth penetration vias 117_3 and 117_5 may be spaced apart from each other with the first penetration via 117_1 therebetween in the second direction D2. The second penetration via 117_2, the first penetration via 117_1 and the fourth penetration via 117_4 may be sequentially arranged in the first direction D1. The fifth penetration via 117_5, the first penetration via 117_1 and the third penetration via 117_3 may be sequentially arranged in the second direction D2.

The penetration via 117 of the first semiconductor chip 110 may be spaced apart from the first insulating pattern 114. The first insulating pattern 114 may include a side portion 114_S disposed between the penetration vias.

The penetration vial 117 may be partially disposed in the first upper insulating layer between the first semiconductor chip 110 and the first insulating pattern 114. The penetration via 117 of the first semiconductor chip 110 may include a conductive material. The penetration via 117 of the first semiconductor chip 110 may be electrically connected to the first lower pad 116. The first upper insulating layer 113 and the first insulating pattern 114 may surround the penetration vias 117 of the first semiconductor chip 110.

The second semiconductor chip 120, the third semiconductor chip 130 and the upper semiconductor chip 140 may be sequentially stacked on the first semiconductor chip 110 in the third direction D3. The third direction D3 may cross the first direction D1 and the second direction D2. For example, the third direction D3 may be a vertical direction perpendicular to the first direction D1 and the second direction D2. The first semiconductor chip 110, the second semiconductor chip 120, the third semiconductor chip 130, the upper semiconductor chip 140 and the base chip 200 may overlap or at least partially overlap each other in the third direction D3.

The first interlayered adhesive layer 161 may be disposed on the first upper insulating layer 113 and the first insulating pattern 114. The second semiconductor chip 120 may be disposed on the first interlayered adhesive layer 161. The second semiconductor chip 120 may be similar to the first semiconductor chip 110. The second semiconductor chip 120 may include a second substrate 121, a second lower insulating layer 122, a second upper insulating layer 123, a second insulating pattern 124, a second line structure 125, a second lower pad 126 and a penetration via 127. Forms of the second upper insulating layer 123 and the second insulating pattern 124 may be similar to forms of the first upper insulating layer 113 and the first insulating pattern 114.

The second interlayered adhesive layer 162 may be disposed on the second upper insulating layer 123 and the second insulating pattern 124. The third semiconductor chip 130 may be disposed on the second interlayered adhesive layer 162. The third semiconductor chip 130 may be similar to the first semiconductor chip 110 and the second semiconductor chip 120. The third semiconductor chip 130 may include a third substrate 131, a third lower insulating layer 132, a third upper insulating layer 133, a third insulating pattern 134, a third line structure 135, a third lower pad 136 and a penetration via 137. Forms of the third upper insulating layer 133 and the third insulating pattern 134 may be similar to forms of the first upper insulating layer 113 and the first insulating pattern 114. However, as understood by one of ordinary skill in the art, the embodiments are not limited to this configuration. For example, the form of the third upper insulating layer 133 may be different from the form of the first upper insulating layer 113, or the form of the third insulating pattern 134 may be different from the first insulating pattern 114.

The third interlayered adhesive layer 163 may be disposed on the third upper insulating layer 133 and the third insulating pattern 134. The upper semiconductor chip 140 may be disposed on the third interlayered adhesive layer 163. Except for what will be described below, the upper semiconductor chip 140 may be similar to the first to third semiconductor chips 110, 120 and 130. However, as understood by one of ordinary skill in the art, at least one of the semiconductor chips 110, 120, 130, and 140 may be different from the other semiconductor chips.

The upper semiconductor chip 140 may include a fourth substrate 141, a fourth lower insulating layer 142, a fourth upper insulating layer 143, a fourth insulating pattern 144, a fourth line structure 145, and a fourth lower pad 146. Forms of the fourth upper insulating layer 143 and the fourth insulating pattern 144 may be similar to forms of the first upper insulating layer 113 and the first insulating pattern 114. However, as understood by one of ordinary skill in the art, the embodiments are not limited to this configuration. For example, the form of the fourth upper insulating layer 143 may be different from the form of the first upper insulating layer 113, or the form of the fourth insulating pattern 144 may be different from the first insulating pattern 114.

A top surface of the fourth upper insulating layer 143, a top surface of the fourth insulating pattern 144 and a top surface of the molding layer 500 may be coplanar or substantially coplanar with each other. According to some embodiments, the upper semiconductor chip 140 may penetrate the fourth substrate 141, and may further include a penetration via electrically connected to the fourth line structure 145. The molding layer 500 may cover the base chip 200, the first to third semiconductor chips 110, 120 and 130 and the upper semiconductor chip 140.

Except for what will be described below, the base chip 200 may be similar to the first to third semiconductor chips 110, 120 and 130, and the upper semiconductor chip 140. The base chip 200 may include a base substrate 210, a fifth lower insulating layer 220, a fifth upper insulating layer 230, a fifth insulating pattern 240, a penetration via 250 and a fifth line structure 260. Forms of the fifth upper insulating layer 230 and the fifth insulating pattern 240 may be similar to forms of the first upper insulating layer 113 and the first insulating pattern 114. However, as understood by one of ordinary skill in the art, at least one of the base chip 200 and semiconductor chips 110, 120, 130, and 140 may be different from the other chips.

The base substrate 210 may be a semiconductor substrate. The penetration via 250 of the base chip 200 may penetrate the base substrate 210. The fifth lower insulating layer 220 may be disposed on a bottom surface of the base substrate 210. The fifth upper insulating layer 230 may be disposed on a top surface of the base substrate 210. A width of the base substrate 210 in the first direction D1 may be greater than widths of the first to third semiconductor chips 110, 120 and 130 in the first direction D1.

The base chip 200 may be a buffer chip. Logic circuits may be disposed on a bottom surface of the base chip 200. The base chip 200 may be disposed on one side of the stack structure 100 to transmit signals of the first to third semiconductor chips 110, 120 and 130 and the upper semiconductor chip 140 outside, and to transmit an external signal to the first to third semiconductor chips 110, 120 and 130 and the upper semiconductor chip 140. According to some embodiments, the semiconductor device may be a high bandwidth memory (HBM) package including stacked memory devices.

Referring to FIGS. 1C, 1D and 1E, the side portions 114_S may include a first side portion 114_S1, a second side portion 114_S2, a third side portion 114_S3 and a fourth side portion 114_S4. Except for what will be described below, the first to fourth side portions 114_S1, 114_S2, 114_S3 and 114_S4 may be similar to each other. Corner portions 114_C may include a first corner portion 114_C1 and a second corner portion 114_C2.

The first side portion 114_S1 and the third side portion 114_S3 may be spaced apart from each other with the first penetration via 117_1 therebetween in the second direction D2. The second side portion 114_S2 and the fourth side portion 114_S4 may be spaced apart from each other with the first penetration via 117_1 therebetween in the first direction D1. The first side portion 114_S1 may be disposed between the first penetration via 117_1 and the third penetration via 117_3. The second side portion 114_S2 may be disposed between the first penetration via 117_1 and the fourth penetration via 117_4. The third side portion 114_S3 may be disposed between the first penetration via 117_1 and the fifth penetration via 117_5. The fourth side portion 114_S4 may be disposed between the first penetration via 117_1 and the second penetration via 117_2.

The first upper insulating layer 113 may be partially disposed between the first side portion 114_S1 and the third side portion 114_S3, and between the second side portion 114_S2 and the fourth side portion 114_S4.

The first corner portion 114_C1 and the second corner portion 114_C2 may be spaced apart from each other with the fourth side portion 114_S4 therebetween in the second direction D2.

The corner portions 114_C may connect the side portions 114_S. The first corner portion 114_C1 may connect the first side portion 114_S1 and the fourth side portion 114_S4. The second corner portion 114_C2 may connect the third side portion 114_S3 and the fourth side portion 114_S4. On a plan view according to FIG. 1C, the corner portion 114_C may have a tetragonal form.

The side portion 114_S may include a first side pattern portion 114_SP1 and a second side pattern portion 114_SP2. The second side pattern portion 114_SP2 may be disposed on the first side pattern portion 114_SP1. The first upper insulating layer 113 may include a first part 113_1, a second part 113_2 and a third part 113_3. The third part 113_3 of the first upper insulating layer 113 may be disposed on the second part 113_2.

The second side pattern portion 113_SP2 may be disposed at a higher level than the first side pattern portion 113_SP1. The third part 113_3 of the first upper insulating layer 113 may be disposed at a higher level than the first part 113_1 and the second part 113_2. The first side pattern portion 114_SP1 may be disposed at the same level as the first part 113_1 and the second part 113_2 of the first upper insulating layer 113. The second side pattern portion 114_SP2 may be disposed at the same level as the third part 113_3 of the first upper insulating layer 113.

The second side pattern portion 114_SP2 may include a first part 114_SP21, a second part 114_SP22 and a third part 114_SP23. The second part 114_SP22 of the second side pattern portion 114_SP2 may overlap the first side pattern portion 114_SP1 in the third direction D3. The first and third parts 114_SP21 and 114_SP23 of the second side pattern portion 114_SP2 may not overlap the first side pattern portion 114_SP1 in the third direction D3.

The first part 113_1 and the second part 113_2 of the first upper insulating layer 113 may be disposed between the first penetration via 117_1 and the first side pattern portion 114_SP1. The third part 113_3 of the first upper insulating layer 113 may be disposed between the first penetration via 117_1 and the second side pattern portion 114_SP2.

The first part 113_1 of the first upper insulating layer 113 may overlap the second side pattern portion 114_SP2 in the third direction D3. The second part 113_2 of the first upper insulating layer 113 may overlap the third part 113_3 of the first upper insulating layer 113 in the third direction D3.

A width W1 of the first side pattern portion 114_SP1 in the first direction D1 may be smaller than a width W2 of the second side pattern portion 114_SP2 in the first direction D1. The width W1 of the first side pattern portion 114_SP1 in the first direction D1 may be the same as a width of the second part 114_SP22 of the second side pattern portion 114_SP2 in the first direction D1. The first side pattern portion 114_SP1 may protrude from the second side pattern portion 114_SP2.

A first sidewall 114_SP1S1 of the first side pattern portion 114_SP1 may be connected to a bottom surface 114_SP21B of the first part 114_SP21 of the second side pattern portion 114_SP2. The bottom surface 114_SP21B of the first part 114_SP21 and the bottom surface 114_SP23B of the third part 114_SP23 of the second side pattern portion 114_SP2 may be spaced apart from each other in the first direction D1. The bottom surface 114_SP1B of the first side pattern portion 114_SP1 may be disposed at a lower level than the bottom surface 114_SP21B of the first part 114_SP21 and the bottom surface 114_SP23B of the third part 114_SP23 of the second side pattern portion 114_SP2.

The sidewall 114_SP21S of the first part 114_SP21 and the sidewall 114_SP23S of the third part 114_SP23 of the second side pattern portion 114_SP2 may be opposed to each other. The sidewall 114_SP21S of the first part 114_SP21 of the second side pattern portion 114_SP2 may be connected to the bottom surface 114_SP21B of the first part 114_SP21 of the second side pattern portion 114_SP2. The sidewall 114_SP21S of the first part 114_SP21 of the second side pattern portion 114_SP2 may be spaced apart from the first sidewall 114_SP1S1 of the first side pattern portion 114_SP1 in the first direction D1.

The sidewall 114_SP23S of the third part 114_SP23 of the second side pattern portion 114_SP2 may be connected to the bottom surface 114_SP23B of the third part 114_SP23 of the second side pattern portion 114_SP2. The sidewall 114_SP23S of the third part 114_SP23 of the second side pattern portion 114_SP2 may be spaced apart from the second sidewall 114_SP1S2 of the first side pattern portion 114_SP1 in the first direction D1.

The bottom surface 114_SP1B of the first side pattern portion 114_SP1 may be in contact with the first part 111_T1 of the top surface 111_T of the first substrate 111. The first part 111_T1 of the top surface 111_T of the first substrate 111 may be disposed between the first penetration via 117_1 and the first penetration via 117_1. The first part 111_T1 of the top surface 111_T of the first substrate 111 may be spaced apart from the first penetration via 117_1 and the first penetration via 117_1 in the first direction D1.

The first side pattern portion 114_SP1 may not overlap the second part 111_T2 of the top surface 111_T of the first substrate 111 in the third direction D3. The second part 111_T2 of the top surface 111_T of the first substrate 111 may be disposed between the first penetration via 117_1 and the second penetration via 117_2. The second part 111_T2 of the top surface 111_T of the first substrate 111 may be in contact with a sidewall of the first penetration via 117_1.

The first part 113_1 of the first upper insulating layer 113 may be in contact with the second sidewall 114_SP1S2 of the first side pattern portion 114_SP1. The first part 113_1 of the first upper insulating layer 113 may be in contact with the bottom surface 114_SP23B of the third part 114_SP23 of the second side pattern portion 114_SP2. The third part 113_3 of the first upper insulating layer 113 may be in contact with the sidewall 114_SP23S of the third part 114_SP23 of the second side pattern portion 114_SP2. The first part 113_1 of the first upper insulating layer 113 may be spaced apart from the first penetration via 117_1 in the first direction D1.

The top surface 114_SP2T of the second side pattern portion 114_SP2, the top surface 113_T of the first upper insulating layer 113 and the top surface 117_T of the penetration via 117 may be coplanar or substantially coplanar with each other.

Sidewalls of the first side pattern portion 114_SP1 and sidewalls of the second side pattern portion 114_SP2 of the first side portion 114_S1 may extend in the first direction D1. Sidewalls of the first side pattern portion 114_SP1 and sidewalls of the second side pattern portion 114_SP2 of the third side portion 114_S3 may extend in the first direction D1.

Sidewalls of the first side pattern portion 114_SP1 and sidewalls of the second side pattern portion 114_SP2 of the second side portion 114_S2 may extend in the second direction D2. Sidewalls 114_SP1S1 and 114_SP1S2 of the first side pattern portion 114_SP1 and sidewalls 114_SP21S of the second side pattern portion 114_SP2 of the fourth side portion 114_S4 may extend in the second direction D2.

The corner portion 114_Cmay include a first corner pattern portion 114_CP1 and a second corner pattern portion 114_CP2. The second corner pattern portion 114_CP2 may be disposed at a higher level than the first corner pattern portion 114_CP1 in the direction D3. The first side pattern portion 114_SP1 may be disposed at the same level as the first side pattern portion 114_SP1. The second corner pattern portion 114_CP2 may be disposed at the same level as the second side pattern portion 114_SP2.

The first corner pattern portion 114_CP1 may be connected to the first side pattern portion 114_SP1. The second corner pattern portion 114_CP2 may be connected to the second side pattern portion 114_SP2. On a plan view according to FIG. 1C, the first corner pattern portion 114_CP1 may have a cross form. On a plan view according to FIG. 1C, the second corner pattern portion 114_CP2 may have a tetragonal form.

The semiconductor device according to some embodiments may include insulating patterns 113, 124, 134, 144 and 240 including an insulating material different from upper insulating layers 113, 123, 133, 143 and 230 on the upper insulating layers 113, 123, 133, 143 and 230 to reduce a warpage phenomenon. Accordingly, stability of the semiconductor device may be improved.

Since in the semiconductor device according to some embodiments, the upper insulating layers 113, 123, 133, 143 and 230 include an oxide, and the insulating patterns 113, 124, 134, 144 and 240 include a nitride, the warpage phenomenon may be reduced.

Since in the semiconductor device according to some embodiments, the insulating patterns 113, 124, 134, 144 and 240 further include the first side pattern portion 114_SP1 having a narrower width than the second side pattern portion 114_SP2, the warpage phenomenon may be reduced.

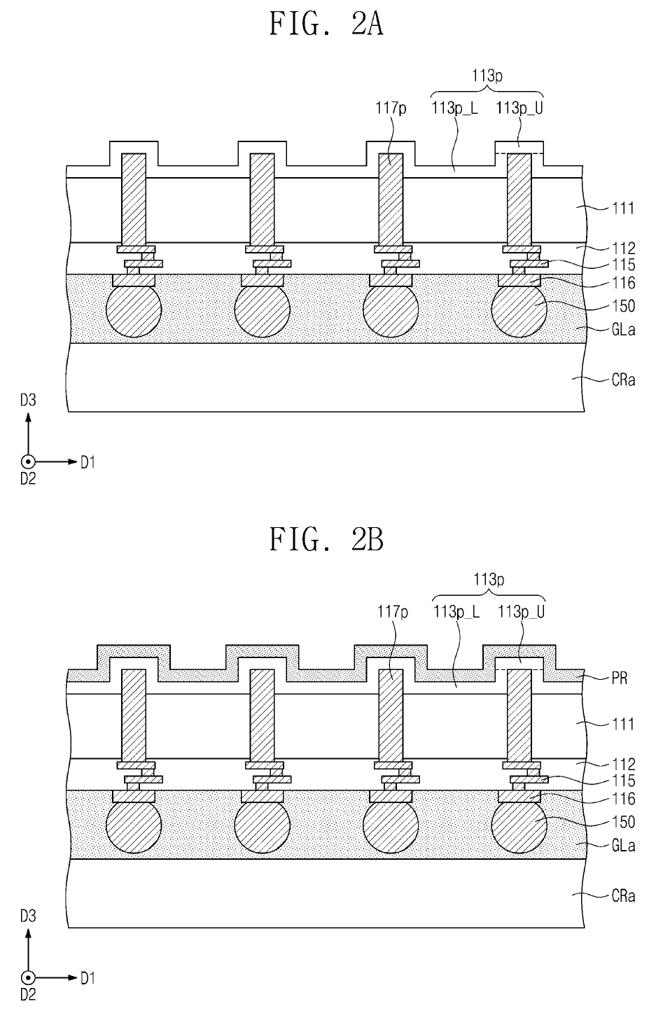

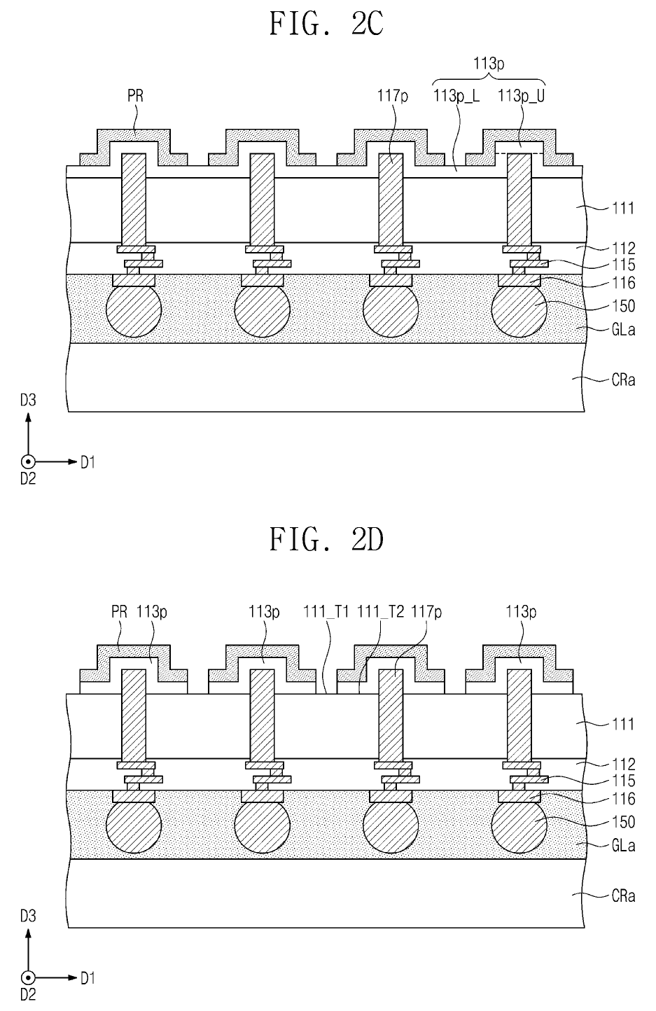

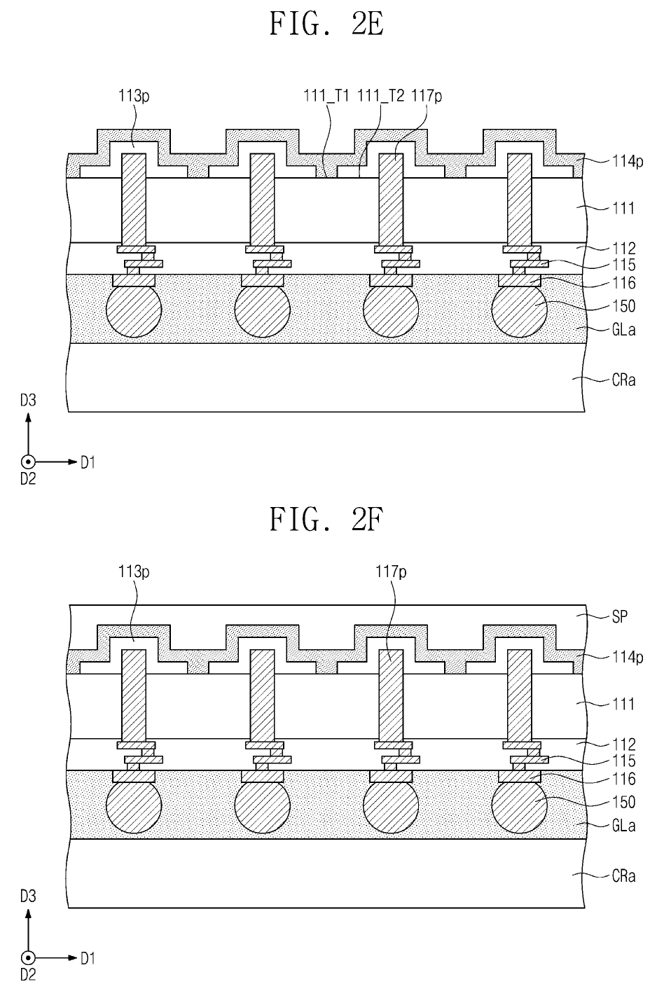

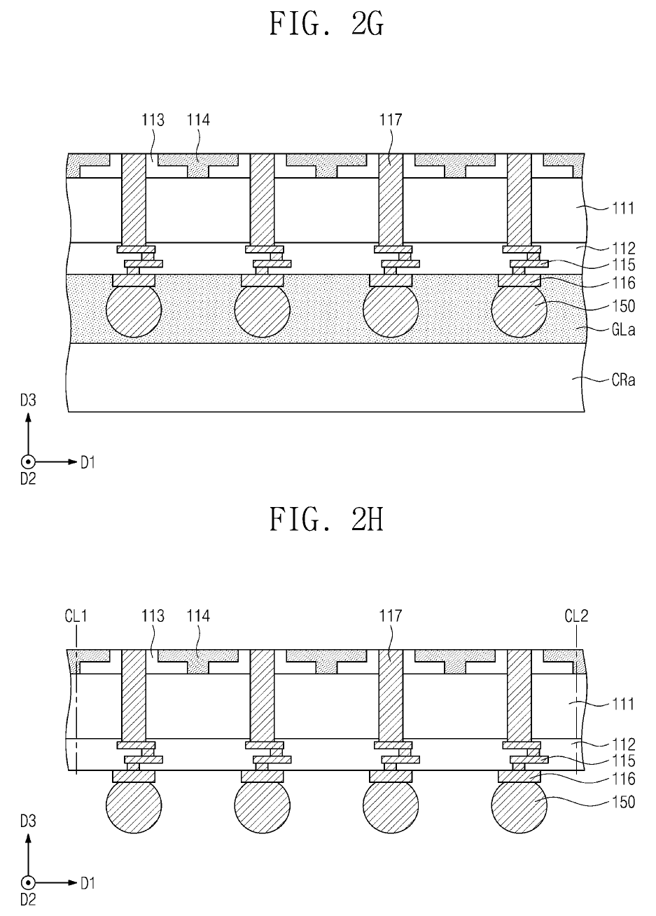

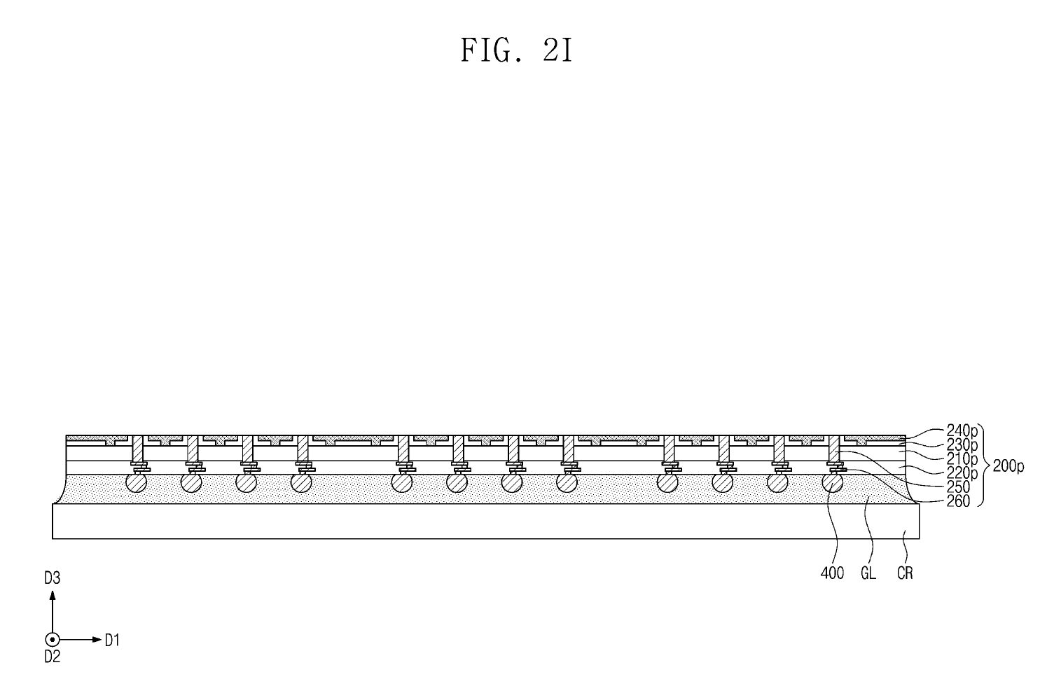

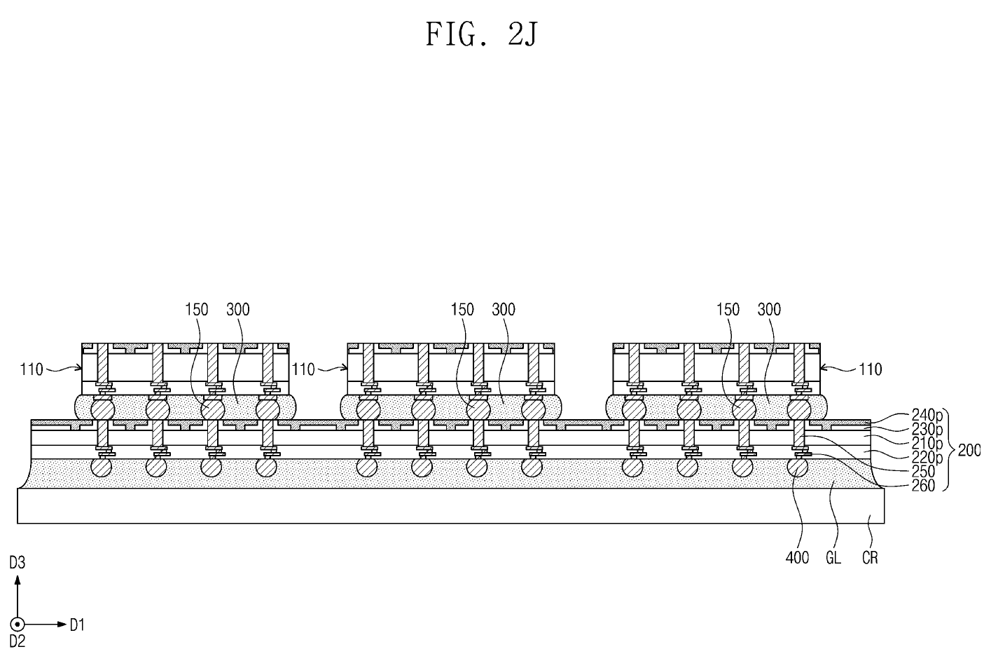

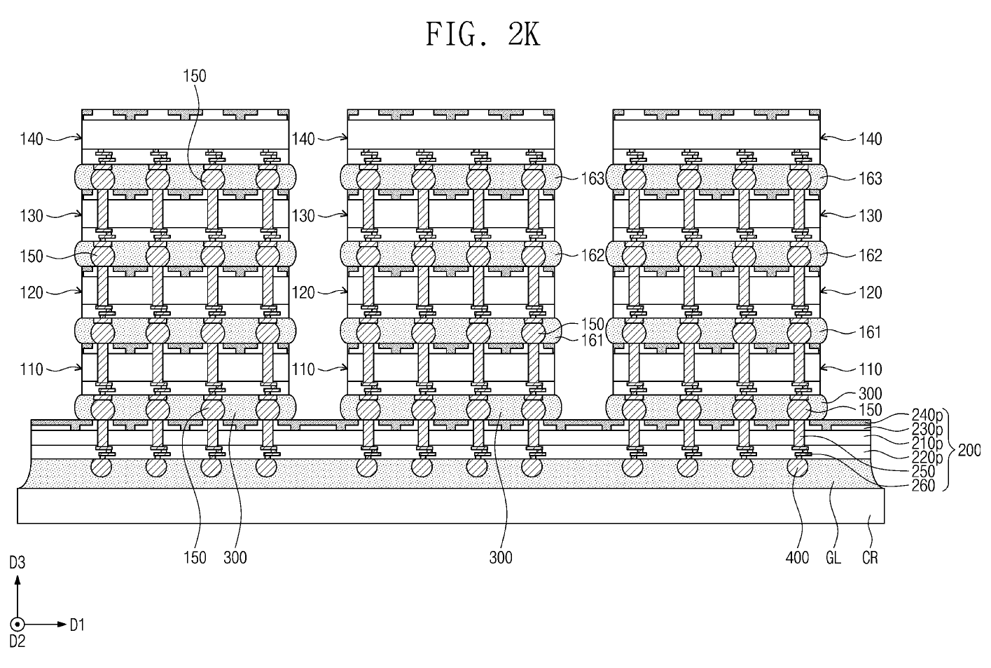

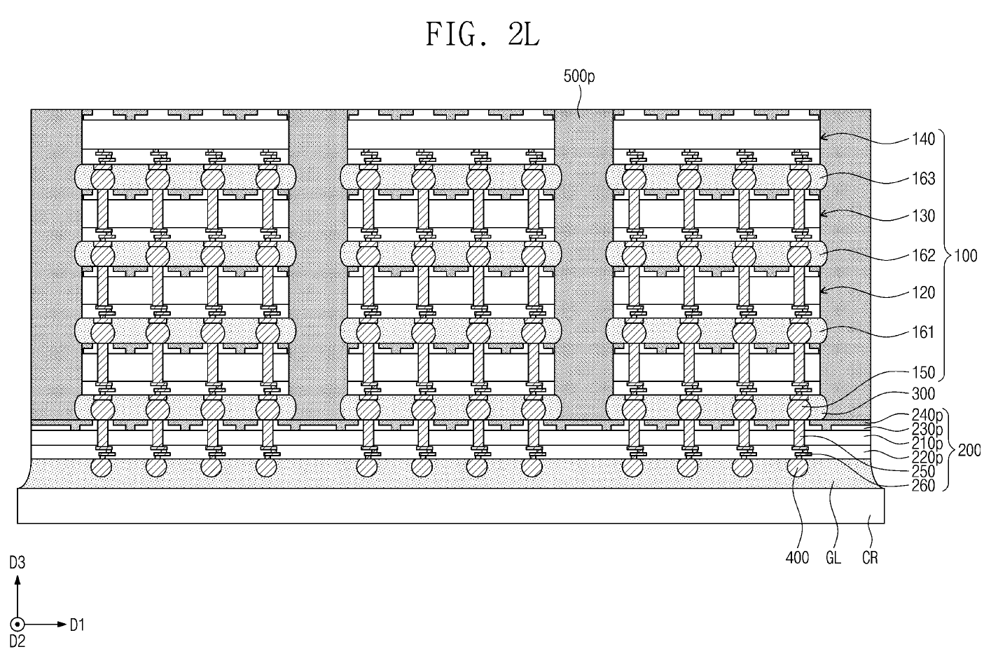

FIGS. 2A, 2B, 2C, 2D, 2E, 2F, 2G, 2H, 2I, 2J, 2K and 2L are diagrams describing a method for manufacturing a semiconductor device according to FIGS. 1A, 1B, 1C, 1D and 1E.

Referring to FIG. 2A, an interlayered connection terminal 150, a first substrate 111, a first lower insulating layer 112, a first line structure 115, a first lower pad 116 and a preliminary penetration via 117p may be provided. The first lower insulating layer 112, the first line structure 115 and the interlayered connection terminal 150 may be disposed on a first adhesive member GLa. The first adhesive member GLa may be disposed on a first carrier substrate CRa.

The preliminary penetration via 117p may penetrate the first substrate 111. The preliminary penetration via 117p may include a conductive material.

A first preliminary upper insulating layer 113p may be formed on the first substrate 111 and the preliminary penetration via 117p. The first preliminary upper insulating layer 113p may cover the first substrate 111 and the preliminary penetration via 117p. The first preliminary upper insulating layer 113p may include an upper portion 113p_U overlapping the preliminary penetration via 117p in the third direction D3, and disposed at a higher level than the preliminary penetration via 117p, and a lower portion 113p_L in contact with the top surface 111_T of the first substrate 111, disposed at the same level as the preliminary penetration via 117p. The first preliminary upper insulating layer 113p may include an insulating material. For example, the first preliminary upper insulating layer 113p may include an oxide material.

Referring to FIG. 2B, a photosensitive layer PR covering the first preliminary upper insulating layer 113p may be formed. The photosensitive layer PR may conformally cover the first preliminary upper insulating layer 113p. The photosensitive layer PR may include a photosensitive material. The photosensitive layer PR may be a photoresist layer that receives light to chemically change.

Referring to FIG. 2C, the photosensitive layer PR may be partially removed. Partially removing the photosensitive layer PR may include performing an exposure process and a develop process. For example, performing the exposure process and the develop process may be a photo process using a photo mask. The photosensitive layer PR may be partially removed to partially expose a top surface of the first preliminary upper insulating layer 113p.

Referring to FIG. 2D, the first preliminary upper insulating layer 113p may be patterned. The first preliminary upper insulating layer 113p may be patterned to expose the first part 111_T1 of the top surface 111_T of the first substrate 111. The first part 111_T1 of the top surface 111_T of the first substrate 111 may be spaced apart from the preliminary penetration via 117p in the first direction D1. The first part 111_T1 of the top surface 111_T of the first substrate 111 may not overlap the first preliminary upper insulating layer 113p in the third direction D3. The second part 111_T2 of the top surface 111_T of the first substrate 111 may overlap the patterned first preliminary upper insulating layer 113p in the third direction D3. The second part 111_T2 of the top surface 111_T of the first substrate 111 may be in contact with the preliminary penetration via 117p. Patterning the first preliminary upper insulating layer 113p may be performed by using the photosensitive layer PR as an etching mask.

Referring to FIG. 2E, the photosensitive layer PR may be removed. A first preliminary insulating pattern 114p covering the first preliminary upper insulating layer 113p and the top surface 111_T of the first substrate 111 may be formed. The first preliminary insulating pattern 114p may include an insulating material. The first preliminary insulating pattern 114p may include an insulating material different from the first preliminary upper insulating layer 113p. For example, the first preliminary insulating pattern 114p may include a nitride. The first preliminary insulating pattern 114p may be in contact with the first part 111_T1 of the top surface 111_T of the first substrate 111 and a sidewall of the first preliminary upper insulating layer 113p.

Referring to FIG. 2F, a sacrificial layer SP covering the first preliminary insulating pattern 114p may be formed. The sacrificial layer SP may include an insulating material. According to some embodiments, the sacrificial layer SP may include the same insulating material as the first preliminary upper insulating layer 113p. For example, the sacrificial layer SP may include an oxide.

Referring to FIG. 2G, a portion of the first preliminary upper insulating layer 113p, a portion of the first preliminary insulating pattern 114p, and the sacrificial layer SP may be etched. Etching the portion of the first preliminary upper insulating layer 113p, the portion of the first preliminary insulating pattern 114p, and the sacrificial layer SP may include performing a chemical mechanical polishing (CMP) process. The first preliminary upper insulating layer 113p, the first preliminary insulating pattern 114p and the preliminary penetration via 117p may be respectively defined as the first upper insulating layer 113, the first insulating pattern 114 and the penetration via 117.

Referring to FIG. 2H, the first adhesive member GLa and the first carrier substrate CRa may be removed. After removing the first adhesive member GLa and the first carrier substrate CRa, a cutting process may be performed along a first cutting line CL1 and a second cutting line CL2.

Referring to FIG. 2I, a second carrier substrate CR, a second adhesive member GL on the second carrier substrate CR, a preliminary base chip 200p on the second adhesive member GL, and the lower connection terminal 400 on a bottom surface of the preliminary base chip 200p may be provided.

The preliminary base chip 200p may include a preliminary base substrate 210p, a fifth preliminary lower insulating layer 220p, a fifth preliminary upper insulating layer 230p, a fifth preliminary insulating pattern 240p, a penetration via 250 and a fifth line structure 260. The preliminary base substrate 210p may be a semiconductor substrate. The fifth preliminary upper insulating layer 220p may include an insulating material. The fifth preliminary upper insulating layer 230p and the fifth preliminary insulating pattern 240p may be formed through processes similar to the processes described in FIGS. 2A-2H.

Referring to FIG. 2J, the lower adhesive layer 300, the interlayered connection terminals 150 and a plurality of first semiconductor chips 110 may be provided. The first semiconductor chip 110 may be formed through processes similar to the processes described in FIGS. 2A-2H. For example, the first semiconductor chip 110 may be coupled onto the preliminary base chip 200p by performing a hot pressing process.

Referring to FIG. 2K, the second semiconductor chip 120, the third semiconductor chip 130, the upper semiconductor chip 140, the interlayered connection terminal 150, the first interlayered adhesive layer 161, the second interlayered adhesive layer 162 and the third interlayered adhesive layer 163 may be formed on the first semiconductor chip 110. The first semiconductor chip 110, the second semiconductor chip 120, the third semiconductor chip 130, the upper semiconductor chip 140, the interlayered connection terminal 150, the first interlayered adhesive layer 161, the second interlayered adhesive layer 162 and the third interlayered adhesive layer 163 may be combined through a process similar to the process described in FIG. 2J. The first semiconductor chip 110, the second semiconductor chip 120, the third semiconductor chip 130, the upper semiconductor chip 140, the interlayered connection terminal 150, the first interlayered adhesive layer 161, the second interlayered adhesive layer 162 and the third interlayered adhesive layer 163 may be defined as the stack structure 100 (see FIG. 1B).

Referring to FIG. 2I, the preliminary molding layer 500p covering the preliminary base chip 200p, the stack structures 100 and the lower adhesive layer 300 may be formed. The preliminary molding layer 500p may include a polymer material.

Referring to FIGS. 1A, 1B, 1C, 1D and 1E, the second carrier substrate CR and the second adhesive member GL may be removed. A cutting process may be performed on the preliminary base chip 200p and the preliminary molding layer 500p. The preliminary base chip 200p on which the cutting process is performed may be defined as the base chip 200. The preliminary base substrate 210p on which the cutting process is performed may be defined as the base substrate 210. The fifth preliminary lower insulating layer 220p on which the cutting process is performed may be defined as the fifth lower insulating layer 220. The fifth preliminary upper insulating layer 230p on which the cutting process is performed may be defined as the fifth upper insulating layer 230. The fifth preliminary insulating pattern 240p on which the cutting process is performed may be defined as the fifth insulating pattern 240. The preliminary molding layer 500p on which the cutting process is performed may be defined as the molding layer 500.

A method for manufacturing a semiconductor device according to some embodiments may include patterning the first preliminary upper insulating layer 113p before forming the first preliminary insulating pattern 114p on the first preliminary upper insulating layer 113p. Accordingly, the first insulating pattern may form the first side pattern portion 114_SP1 (see FIG. 1D). Accordingly, a warpage phenomenon in a hot pressing process may be reduced.

A method for manufacturing a semiconductor device according to some embodiments may include patterning the first preliminary upper insulating layer 113p before forming the first preliminary insulating pattern 114p on the first preliminary upper insulating layer 113p. Accordingly, the first side pattern portion 114_SP1 may be formed along a pattern of the patterned first preliminary upper insulating layer 113p. Through such a process, a form of the first side pattern portion 114_SP1 may be differently formed along a generation direction of the warpage. The warpage phenomenon may be reduced by making the form of the first side pattern portion 114_SP1 different along the direction of the warpage.

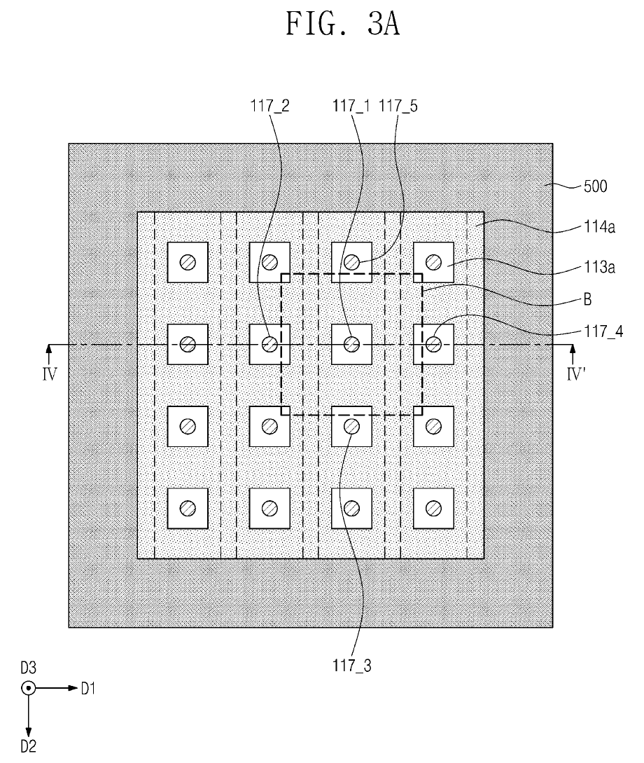

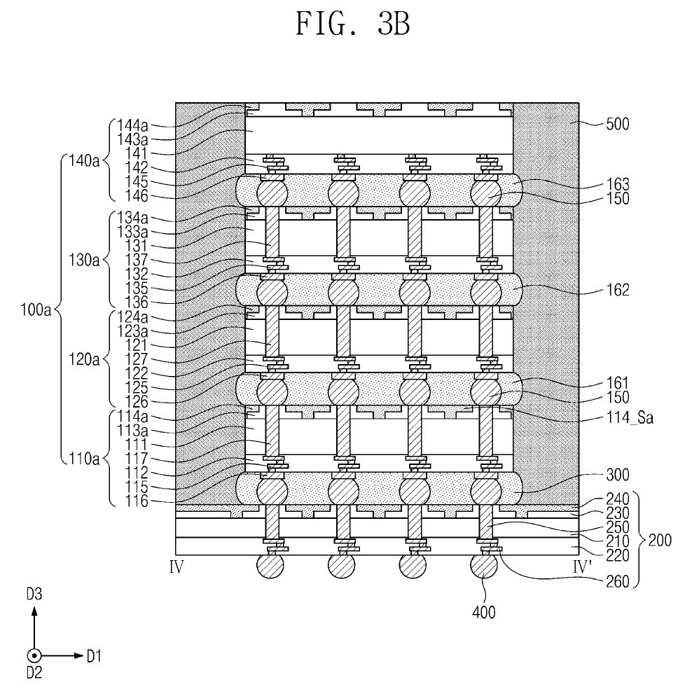

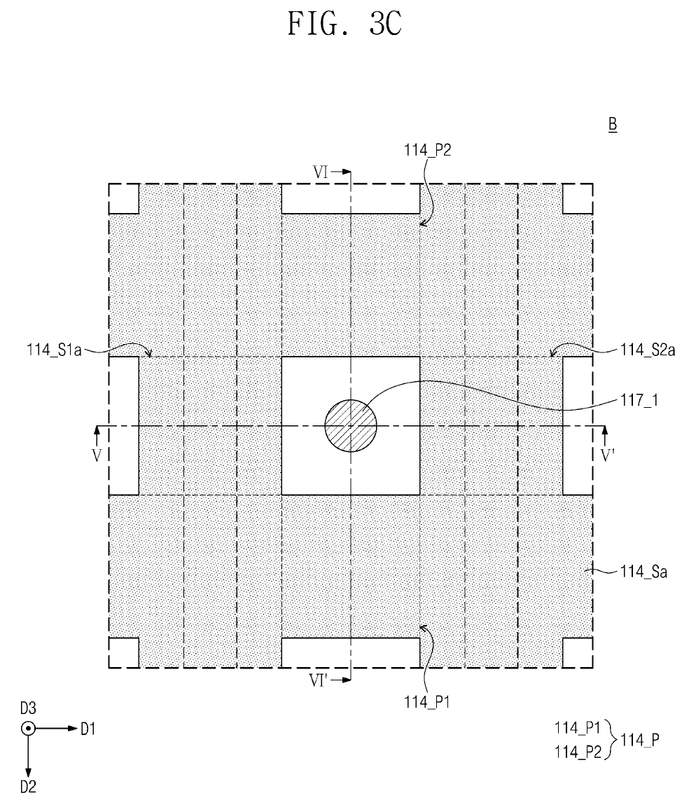

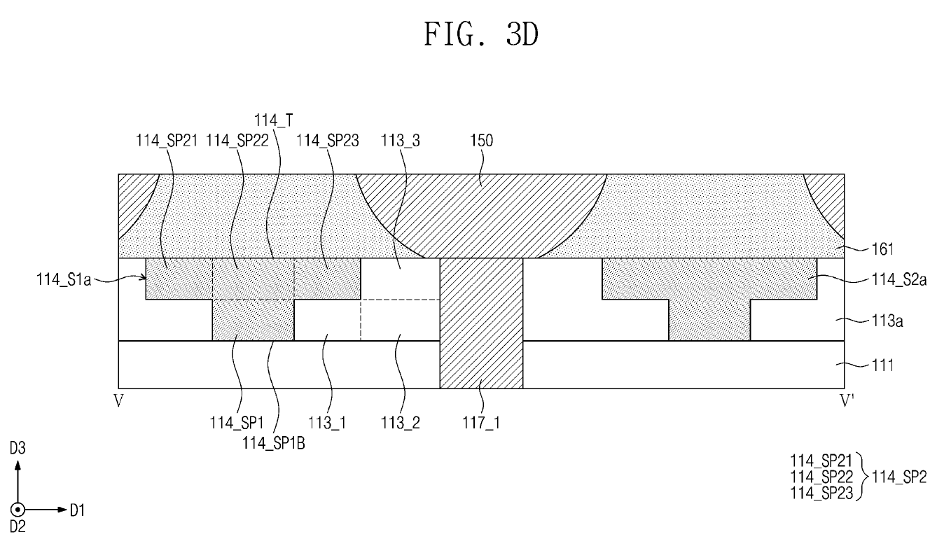

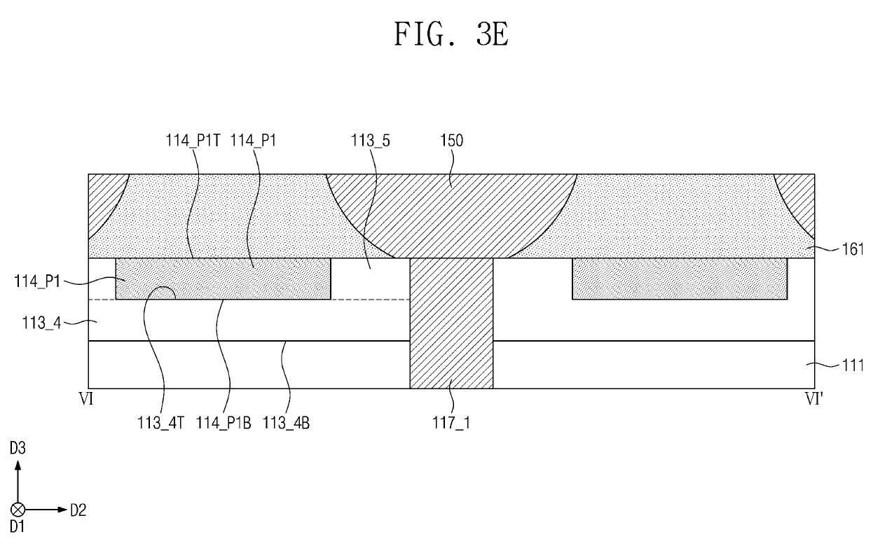

FIGS. 3A, 3B, 3C, 3D and 3E are diagrams illustrating a semiconductor device according to some embodiments. FIG. 3B is a cross-sectional view taken along line IV-IV’ of FIG. 3A. FIG. 3C is an enlarged view of region B of FIG. 3A. FIG. 3D is a cross-sectional view taken along line V-V’ of FIG. 3C. FIG. 3E is a cross-sectional view taken along line VI-VI’ of FIG. 3C. Except for what will be described below, a semiconductor device according to FIGS. 3A and 3E may be similar to the semiconductor device according to FIGS. 1A to 1E.

Referring to FIGS. 3A, 3B, 3C, 3D and 3E, a stack structure 100a may include a first semiconductor chip 110a, a second semiconductor chip 120a, a third semiconductor chip 130a and an upper semiconductor chip 140a. The first semiconductor chip 110a may include a first upper insulating layer 113a and a first insulating pattern 114a. The second semiconductor chip 120a may include a second upper insulating layer 123a and a second insulating pattern 124a. The third semiconductor chip 130a may include a third upper insulating layer 133a and a third insulating pattern 134a. The upper semiconductor chip 140a may include a fourth upper insulating layer 143a and a fourth insulating pattern 144a.

The first insulating pattern 114a may include a side portion 114_Sa disposed between the penetration vias 117 of the first semiconductor chip 110a. The side portion 114_Sa of the first insulating pattern 114a may include a first side portion 114_S1a and a second side portion 114_S2a. The first side portion 114_S1a may be disposed between the first penetration via 117_1 and the second penetration via 117_2. The second side portion 114_S2a may be disposed between the first penetration via 117_1 and the fourth penetration via 117_4.

The first insulating pattern 114a may include a planarization portion 114_P disposed between the penetration vias 117 of the first semiconductor chip 110a. The planarization portion 114_P of the first insulating pattern 114a may include a first planarization portion 114_P1 and a second planarization portion 114_P2. The first planarization portion 114_P1 may be disposed between the first penetration via 117_1 and the third penetration via 117_3. The second planarization portion 114_P2 may be disposed between the first penetration via 117_1 and the fifth penetration via 117_5. The first penetration via 117_1 may be disposed between the first planarization portion 114_P1 and the second planarization portion 114_P2.

The first upper insulating layer 113a may include the fourth part 113_4 overlapping the first planarization portion 114_P1 and the fifth part 113_5 disposed at the same level as the first planarization portion 114_P1. The fourth part 113_4 of the first upper insulating layer 113a may overlap the fifth part 113_5 in the third direction D3. The fourth part 113_4 of the first upper insulating layer 113a may be disposed at a lower level than the fifth part 113_5. The first planarization portion 114_P1 may be disposed at the same level as the second side pattern portion 114_SP2. A thickness of the first planarization portion 114_P1 in the third direction D3 may be the same as a thickness of the second side pattern portion 114_SP2 in the third direction D3.

A top surface 113_4T of the fourth part 113_4 of the first upper insulating layer 113a may be in contact with the bottom surface 114_P1B of the first planarization portion 114_P1. A bottom surface 113_4B of the fourth part 113_4 of the first upper insulating layer 113a may be in contact with the top surface 111_T of the first substrate 111. The fifth part 113_5 of the first upper insulating layer 113a may be in contact with a sidewall of the first planarization portion 114_P1.

Upper surfaces and bottom surfaces of planarization portions of the first insulating pattern 114a may be flat or substantially flat. The top surface 114_P1T and the bottom surface 114_P1B of the first planarization portion 114_P1 may be flat or substantially flat. The top surface 114_P1T and the bottom surface 114_P1B of the first planarization portion 114_P1 may be parallel to each other. The top surface 114_P1T and the bottom surface 114_P1B of the first planarization portion 114_P1 may be parallel to the top surface 111_T of the first substrate 111. The top surface 114_P1T of the first planarization portion 114_P1 may be coplanar or substantially coplanar with a top surface of the fifth part 113_5 of the first upper insulating layer 113a. According to some embodiments, on a cross-sectional view according to FIG. 3E, a planarization portion of the first insulating pattern 114a may have a tetragonal form.

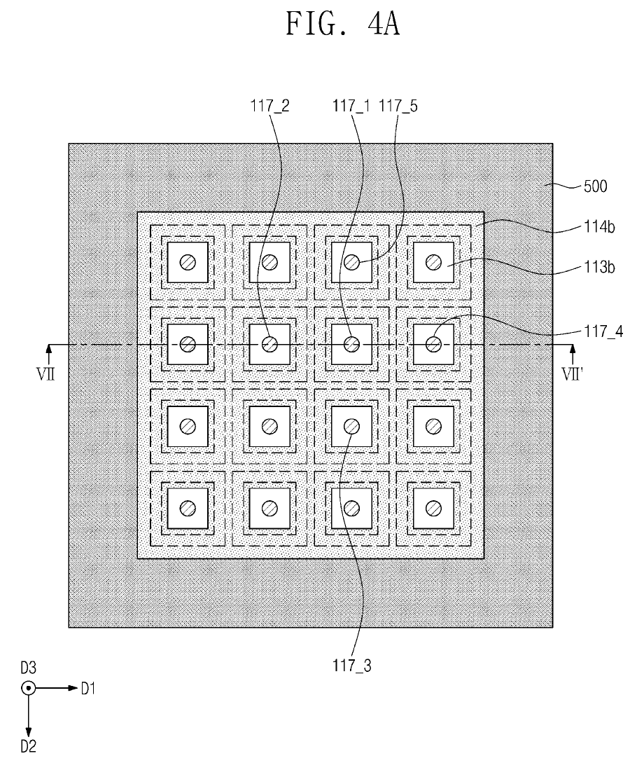

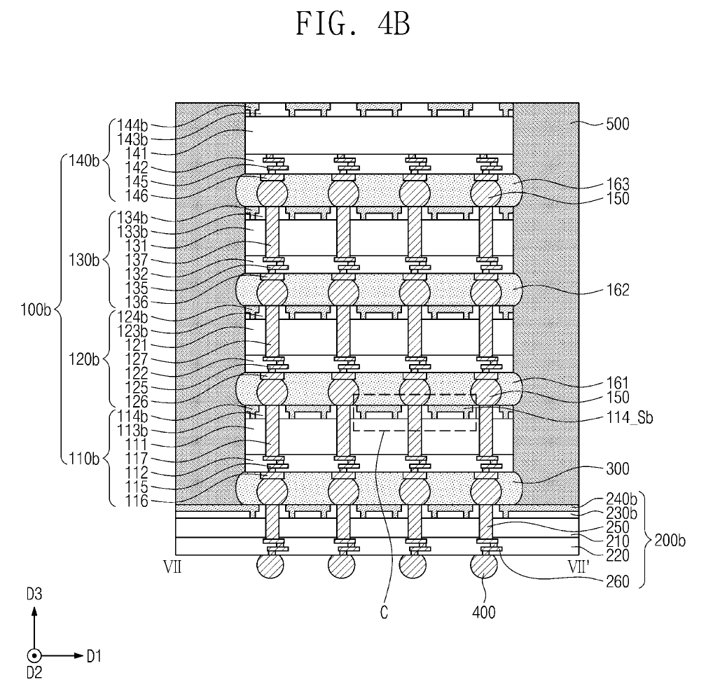

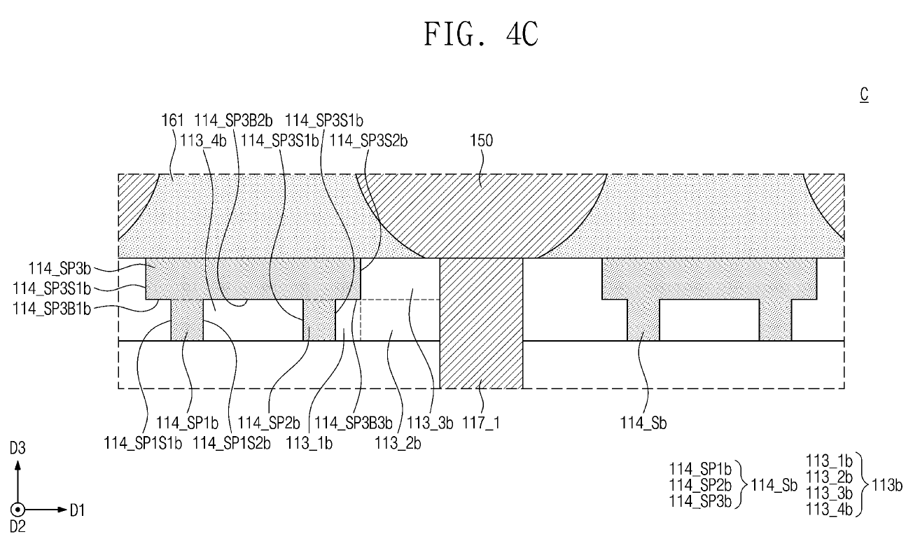

FIGS. 4A, 4B and 4C are diagrams illustrating a semiconductor device according to some embodiments. FIG. 4B is a cross-sectional view taken along line VII-VII’ of FIG. 4A. FIG. 4C is an enlarged view of region C of FIG. 4B. Except for what will be described below, a semiconductor device according to FIGS. 4A, 4B and 4C may be similar to the semiconductor device according to FIGS. 1A-1E. FIG. 4C may correspond to FIG. 1D.

Referring to FIGS. 4A, 4B and 4C, a stack structure 100b may include a first semiconductor chip 110b, a second semiconductor chip 120b, a third semiconductor chip 130b and an upper semiconductor chip 140b. The stack structure 100b may be disposed on a base chip 200b. The first semiconductor chip 110b may include a first upper insulating layer 113b and a first insulating pattern 114b. The second semiconductor chip 120b may include a second upper insulating layer 123b and a second insulating pattern 124b. The third semiconductor chip 130b may include a third upper insulating layer 133b and a third insulating pattern 134b. The upper semiconductor chip 140b may include a fourth upper insulating layer 143b and a fourth insulating pattern 144b. The second base chip 200b may include a fifth upper insulating layer 230b and a fifth insulating pattern 240b.

The first insulating pattern 114b may include a side portion 114_Sb. The side portion 114_Sb of the first insulating pattern 114b may include a first side pattern portion 114_SP1b, a second side pattern portion 114_SP2b and a third side pattern portion 114_SP3b. The first side pattern portion 114_SP1b and the second side pattern portion 114_SP2b may overlap the third side pattern portion 114_SP3b in the third direction D3. The first side pattern portion 114_SP1b and the second side pattern portion 114_SP2b may be disposed at a lower level than the third side pattern portion 114_SP3b. The first side pattern portion 114_SP1b and the second side pattern portion 114_SP2b may be spaced apart from each other in the first direction D1.

The first upper insulating layer 113b may include a first part 113_1boverlapping the third side pattern portion 114_SP3bin the third direction D3, a second part 113_2bconnected to the first part 113_1b, a third part 113_3bin contact with a sidewall of the third side pattern portion 114_SP3band a fourth part 113_4bdisposed between the first side pattern portion 114_SP1band the second side pattern portion 114_SP2b.

The first part 113_1b, the second part 113_2b, the fourth part 113_4b, the first side pattern portion 114_SP1band the second side pattern portion 114_SP2bof the first upper insulating layer 113b may be disposed at the same level. The third side pattern portion 114_SP3bmay include a first bottom surface 114_SP3B1b, a second bottom surface 114_SP3B2band a third bottom surface 114_SP3B3b.

The first bottom surface 114_SP3B1b, the second bottom surface 114_SP3B2b and the third bottom surface 114_SP3B3b of the third side pattern portion 114_SP3b may be spaced apart from each other in the first direction D1. The first bottom surface 114_SP3B1b, the second bottom surface 114_SP3B2b and the third bottom surface 114_SP3B3b of the third side pattern portion 114_SP3b may be disposed at the same level.

The first bottom surface 114_SP3B1b of the third side pattern portion 114_SP3b may be connected to a first sidewall 114_SP3S1b of the third side pattern portion 114_SP3b and a first sidewall 114_SP1S1b of the first side pattern portion 114_SP1b. The second bottom surface 114_SP3B2b of the third side pattern portion 114_SP3b may be connected to a second sidewall 114_SP1S2b of the first side pattern portion 114_SP1b and a first sidewall 114_SP2S1b of the second side pattern portion 114_SP2b. A third bottom surface 114_SP3B3b of the third side pattern portion 114_SP3b may be connected to a second sidewall 114_SP2S2b of the second side pattern portion 114_SP2b.

The second part 113_4b of the first upper insulating layer 113b may be in contact with a second sidewall 114_SP1S2b of the first side pattern portion 114_SP1b, a first sidewall 114_SP2S1b of the second side pattern portion 114_SP2b and a Bottom surface 114_SP3B2b of the third side pattern portion 114_SP3b. The first part 113_1 of the first upper insulating layer 113 may be in contact with the bottom surface 114_SP3B3b of the third side pattern portion 114_SP3b and the second sidewall 114_SP3S2b of the second side pattern portion 114_SP2b.

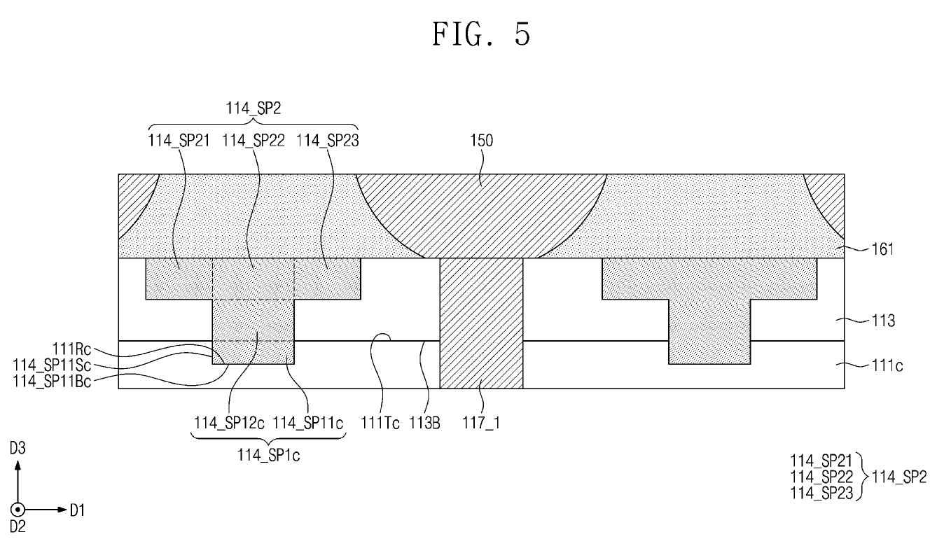

FIG. 5 is a diagram illustrating a semiconductor device according to some embodiments. Except for what will be described below, a semiconductor device according to FIG. 5 may be similar to the semiconductor device according to FIGS. 1A-1E. FIG. 5 may correspond to FIG. 1D.

Referring to FIG. 5, a first side pattern portion 114_SP1c may penetrate a top surface 111_Tc of the first substrate 111. The first side pattern portion 114_SP1c may penetrate a bottom surface 113B of the first upper insulating layer 113.

The first side pattern portion 114_SP1c may include a first part 114_SP11c and a second part 114_SP12c. The first part 114_SP11c of the first side pattern portion 114_SP1c may overlap the second part 114_SP12c in the third direction D3. The first part 114_SP11c of the first side pattern portion 114_SP1c may be disposed at a lower level than the second part 114_SP12c.

A bottom surface 114_SP11Bc of the first part 114_SP11c of the first side pattern portion 114_SP1c may be disposed at a lower level than a top surface 111Tc of the first substrate 111c. A sidewall 114_SP11Sc of the first part 114_SP11C of the first side pattern portion 114_SP1c may be in contact with the first substrate 111c. The first substrate 111c may include a recess 111Rc, and the first part 114_SP11c of the first side pattern portion 114_SP1c may be disposed on the recess 111Rc. A Bottom surface 114_SP11Bc and a sidewall 114_SP11Sc of the first part 114_SP11c of the first side pattern portion 114_SP1c may be in contact with the recess 111Rc of the first substrate 111c.

The bottom surface 114_SP11Bc of the first part 114_SP11c of the first side pattern portion 114_SP1c may be spaced apart from the top surface 111_Tc of the first substrate 111c in the third direction D3. The bottom surface 114_SP11Bc of the first part 114_SP11c of the first side pattern portion 114_SP1c may be spaced apart from the bottom surface 113_B of the first upper insulating layer 113 in the third direction D3.

In the semiconductor device according to some embodiments, since the first side pattern portion 114_SP1c includes the first part 114_SP11c and the second part 114_SP12c, a thickness of the first side pattern portion 114_SP1c in the third direction D3 may be relatively great. Accordingly, a warpage phenomenon may be effectively reduced.

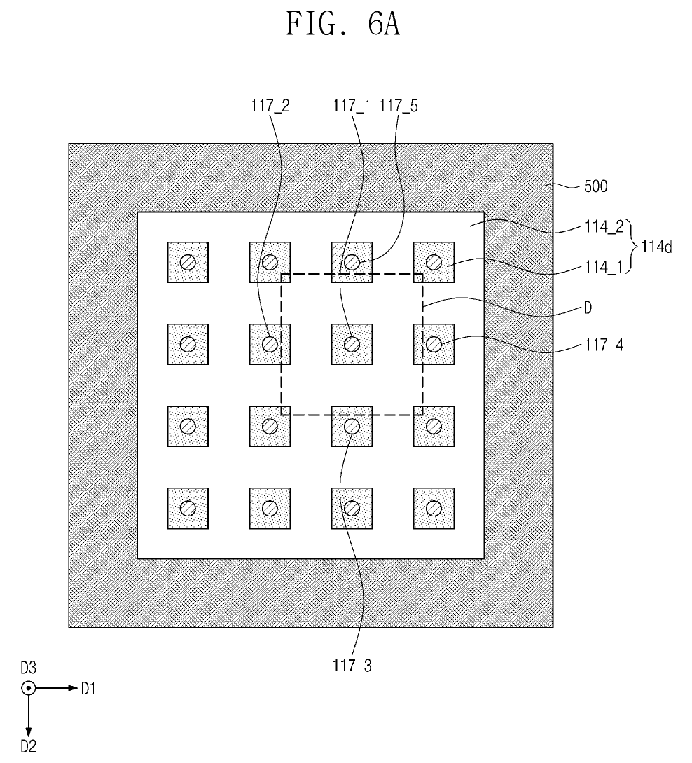

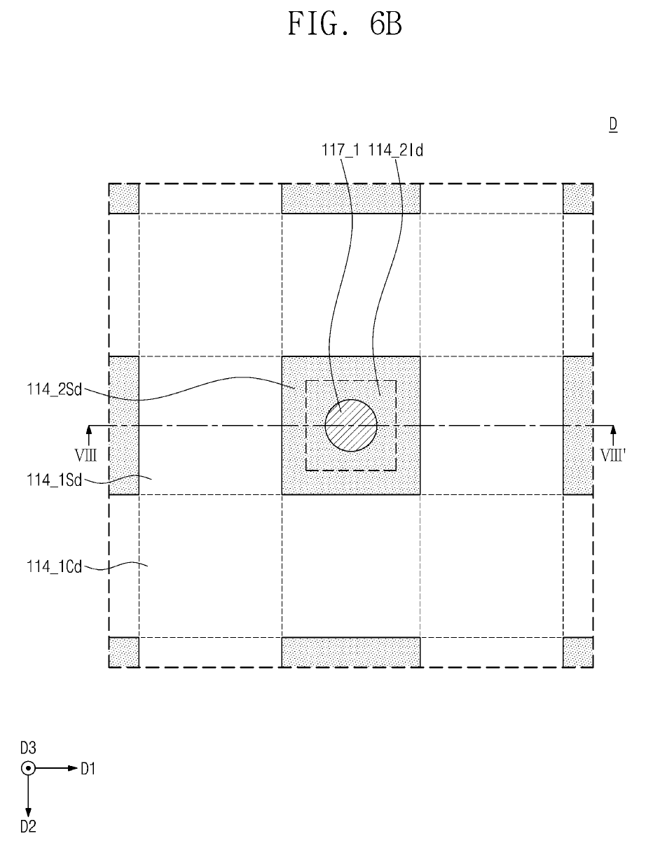

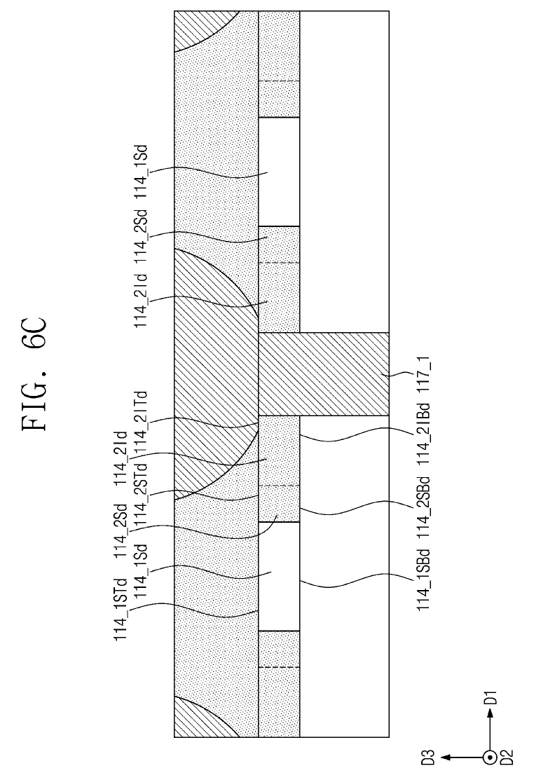

FIGS. 6A, 6B and 6C are diagrams illustrating a semiconductor device according to some embodiments. FIG. 6 is an enlarged view of region D of FIG. 6A. FIG. 6C is a cross-sectional view taken along line VIII-VIII’ of FIG. 6B. Except for what will be described below, a semiconductor device according to FIGS. 6A, 6B, and 6C, may be similar to the semiconductor device according to FIGS. 1A-1E.

Referring to FIGS. 6A, 6B and 6C, a first insulating pattern 114d may include a first part 114_1d including a first insulating material and a second part 114_2d including a second insulating material. The first insulating material and the second insulating material may be different from each other. For example, the first insulating material may include an oxide material, and the second insulating material may include a nitride material.

The first part 114_1d of the first insulating pattern 114d may include a side portion 114_1Sd disposed between the penetration vias 117 and a corner portion 114_1Cd disposed between the side portions 114_1Sd.

The second part 114_2d of the first insulating pattern 114d may include a side portion 114_2Sd in contact with the side portion 114_1Sd of the first part 114_1d and an inner side portion 114_2Id spaced apart from the first part 114_1d of the first insulating pattern 114d. The inner side portion 114_2Id of the second part 114_2d of the first insulating pattern 114d may surround the first penetration via 117_1. The inner side portion 114_2Id of the second part 114_2d of the first insulating pattern 114d may be in contact with a sidewall of the first penetration via 117_1.

A side portion 114_1Sd of the first part 114_1d of the first insulating pattern 114d and a side portion 114_2Sd of the second part 114_2d of the first insulating pattern 114d may correspond to the side portion 114_S of the first insulating pattern 114 according to FIGS. 1A-1E. The side portion 114_1Sd of the first part 114_1d of the first insulating pattern 114d may correspond to the second part 114_SP22 of the second side pattern portion 114_SP2 of the side portion 114_S of the first insulating pattern 114. The side portion 114_2Sd of the second part 114_2d of the first insulating pattern 114d may correspond to the first part 114_SP21 or the third part 114_S23 of the second side pattern portion 114_SP2 of the side portion 114_S of the first insulating pattern 114.

The bottom surface 114_1SBd of the side portion 114_1Sd of the first part 114_1d, the bottom surface 114_2SBd of the side portion 114_2Sd of the second part 114_2d and the bottom surface 114_2IBd of the inner side portion 114_2Id of the second part 114_2d, of the first insulating pattern 114d may be coplanar or substantially coplanar with each other.

The top surface 114_1STd of the side portion 114_1Sd of the first part 114_1d, the top surface 114_2STd of the side portion 114_2Sd of the second part 114_2d and the top surface 114_2ITd of the inner side portion 114_2Id of the second part 114_2d, of the first insulating pattern 114d may be coplanar or substantially coplanar with each other.

Thicknesses in the third direction D3 of the side portion 114_1Sd of the first part 114_1d, the side portion 114_2Sd of the second part 114_2d and the inner side portion 114_2Id of the second part 114_2d, of the first insulating pattern 114d may be the same as each other. The side portion 114_1Sd of the first part 114_1d, the side portion 114_2Sd of the second part 114_2d and the inner side portion 114_2Id of the second part 114_2d, of the first insulating pattern 114d may be disposed at the same level as each other. The side portion 114_1Sd of the first part 114_1d of the first insulating pattern 114d may be in contact with the side portion 114_2Sd of the second part 114_2d.

In a semiconductor device according to some embodiments, the first insulating pattern 114d may include the first part 114_1d and the second part 114_2d including different insulating materials. According to a warpage direction of the semiconductor device, the first part 114_1d and the second part 114_2d of the first insulating pattern 114d may be patterned in different forms. Accordingly, a warpage phenomenon may be effectively reduced.

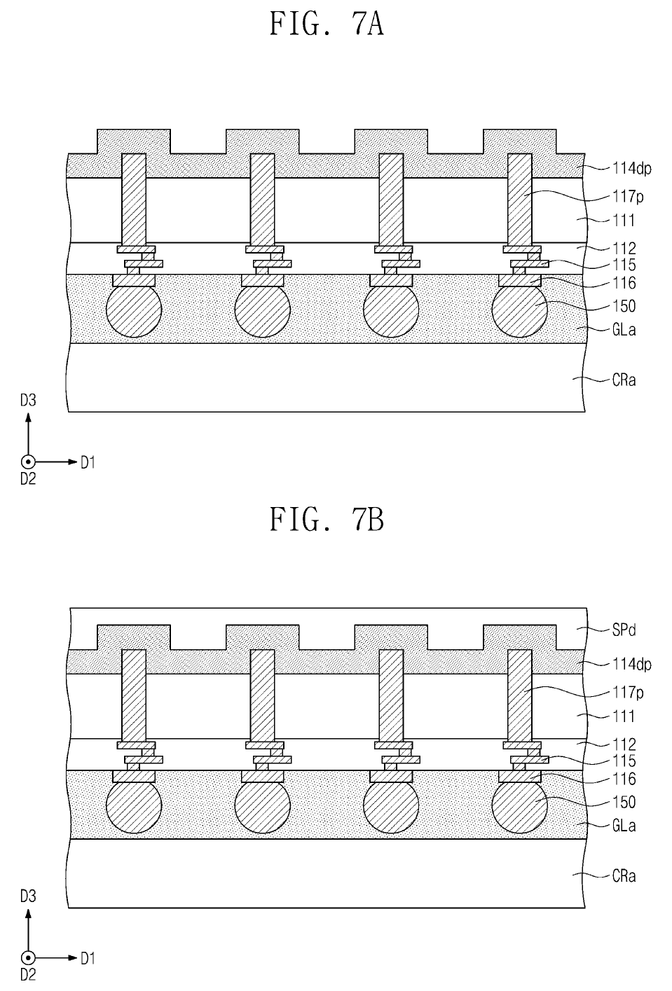

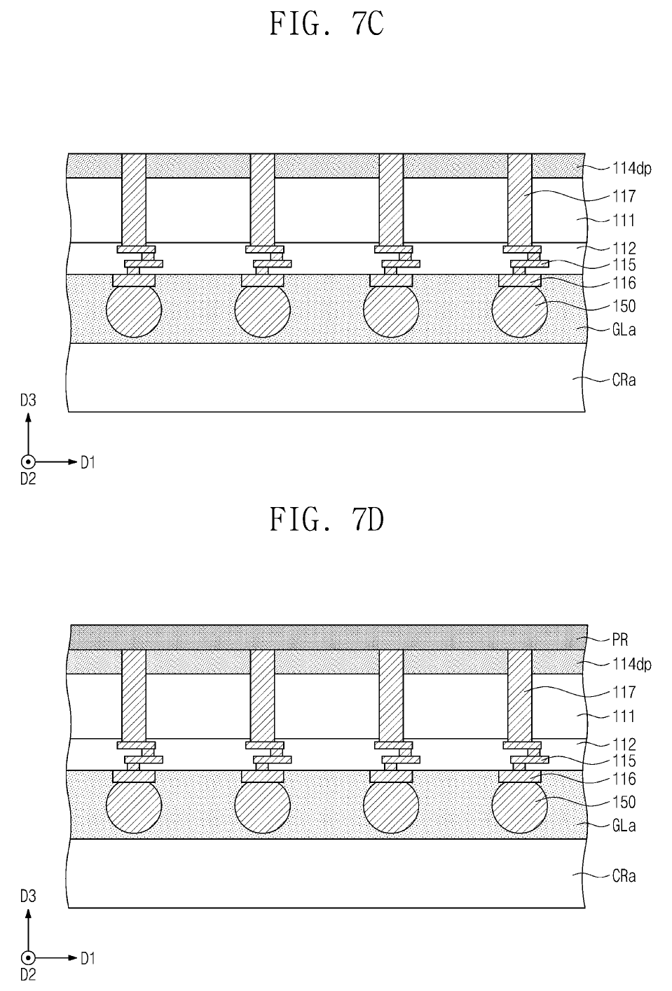

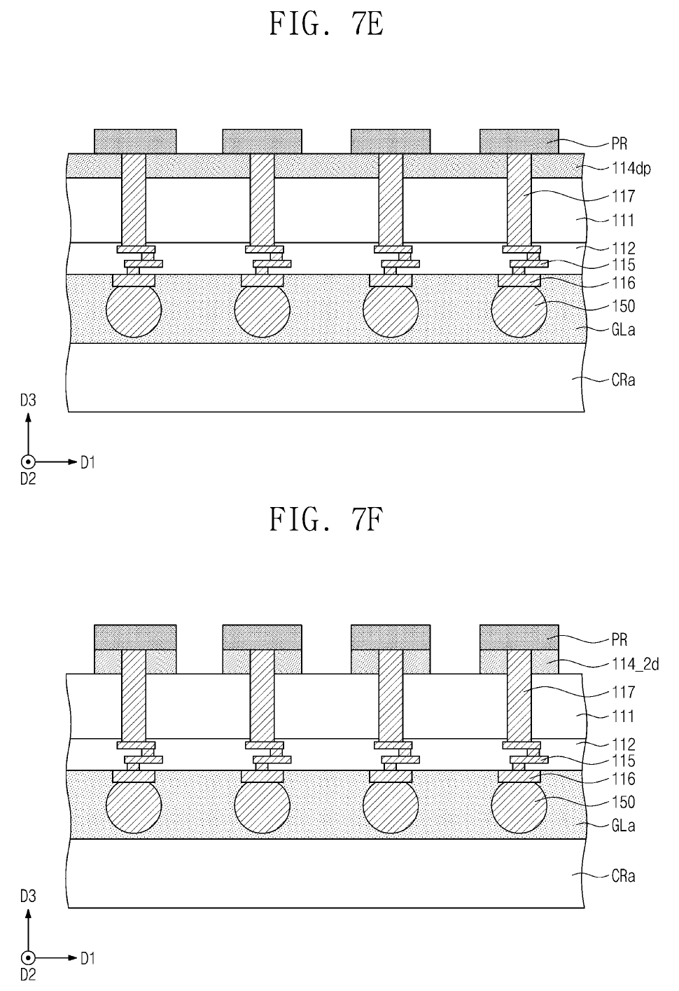

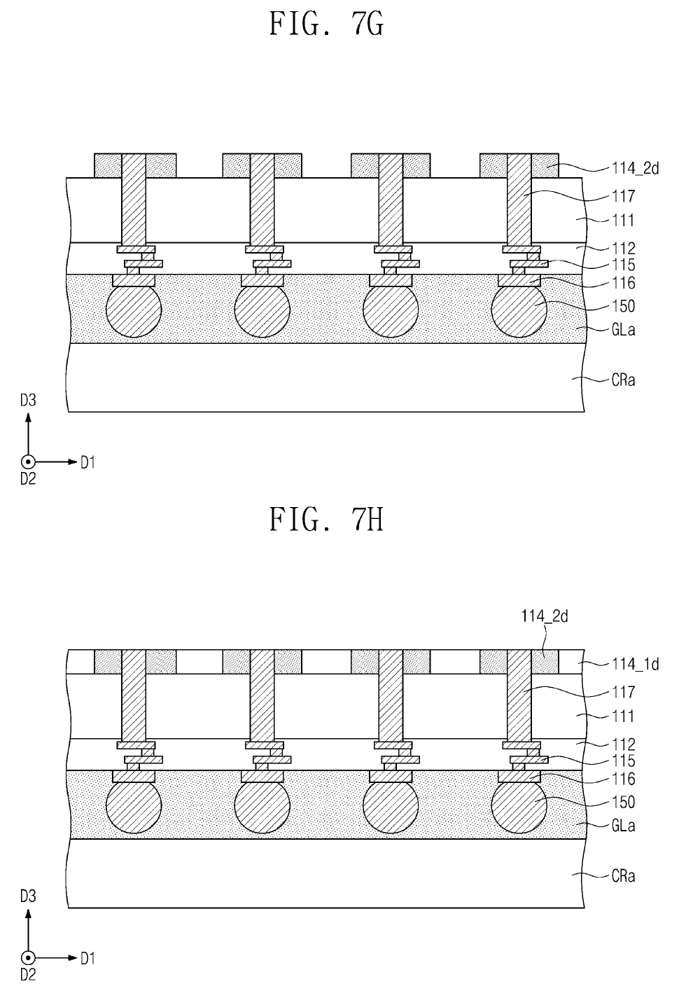

FIGS. 7A, 7B, 7C, 7D, 7E, 7F, 7G and 7H are diagrams describing a method for manufacturing a semiconductor device according to FIGS. 6A, 6B and 6C. Except for what will be described below, a method for manufacturing a semiconductor device according to FIGS. 7A, 7B, 7C, 7D, 7E, 7F, 7G and 7H may be similar to the method for manufacturing a semiconductor device according to FIGS. 2A-2L.

Referring to FIG. 7A, a first preliminary insulating pattern 114dp may be formed on the first substrate 111. The first preliminary insulating pattern 114dp may include an insulating material. For example, the first preliminary insulating pattern 114dp may include a nitride. The first preliminary insulating pattern 114dp may conformally cover the first substrate 111 and the preliminary penetration via 117p.

Referring to FIG. 7B, a sacrificial layer SPd may be formed on the first preliminary insulating pattern 114dp. The sacrificial layer SPd may include an insulating material. For example, the sacrificial layer SPd may include an oxide.

Referring to FIG. 7C, the sacrificial layer SPd and the first preliminary insulating pattern 114dp may be partially etched. Partially etching the sacrificial layer SPd and the first preliminary insulating pattern 114dp may include performing a chemical mechanical polishing (CMP) process. A top surface of the partially etched first preliminary insulating pattern 114dp may be coplanar or substantially coplanar with a top surface of the penetration via 117.

Referring to FIG. 7D, a photosensitive layer PR may be formed on the partially etched first preliminary insulating pattern 114dp.

Referring to FIG. 7E, the photosensitive layer PR may be patterned.

Referring to FIG. 7F, the first preliminary insulating pattern 114dp may be patterned. Patterning the first preliminary insulating pattern 114dp may be performed by using the patterned photosensitive layer PR as an etching mask. The patterned first preliminary insulating pattern 114dp may be defined as a second part 114_2d of the first insulating pattern 114d. The first preliminary insulating pattern 114dp may be patterned to partially expose the top surface 111_T of the first substrate 111.

Referring to FIG. 7G, the photosensitive layer PR may be removed.

Referring to FIG. 7H, the first part 114_1d of the first insulating pattern 114d may be formed. Forming the first part 114_1d of the first insulating pattern 114d may include forming an insulating structure covering a portion of the top surface 111_T of the first substrate 111, the penetration via 117 and the second part 114_2d of the first insulating pattern 114d, and partially etching the insulating structure.

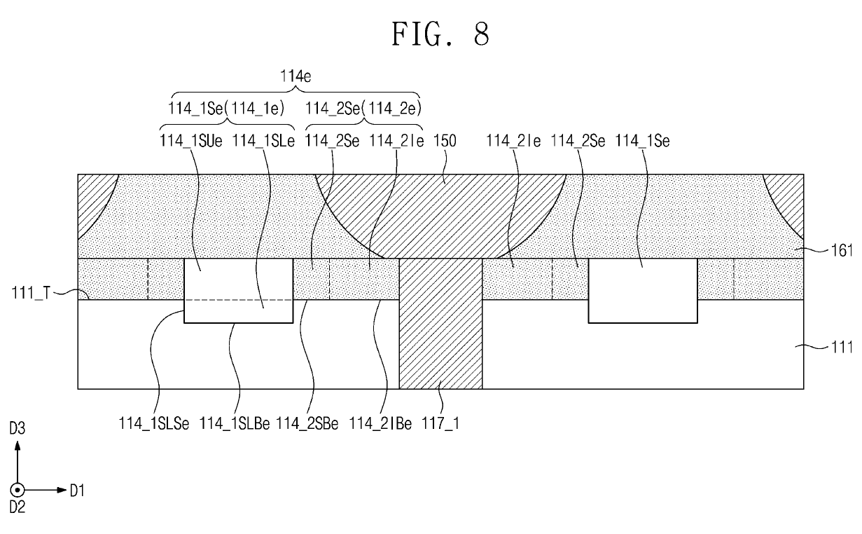

FIG. 8 is a diagram illustrating a semiconductor device according to some embodiments. Except for what will be described below, a semiconductor device according to FIG. 8 may be similar to the semiconductor device according to FIGS. 6A-6C. FIG. 8 may correspond to FIG. 6C.

Referring to FIG. 8, a side portion 114_1S of a first part 114_1e of the first insulating pattern 114e may include a lower portion 114_1SLe and an upper portion 114_1SUe. The side portion 114_1Se of the first part 114_1e of the first insulating pattern 114e may correspond to the second part 114_SP22 of the second side pattern portion 114_SP of the first insulating pattern 114. The side portion 114_1S of the first part 114_1e of the first insulating pattern 114e may correspond to the first side pattern portion 114_SP1 of the first insulating pattern 114.

The upper portion 114_1SUe of the side portion 114_1S of the first part 114_1e of the first insulating pattern 114e may overlap the lower portion 114_1SLe in the third direction D3. The upper portion 114_1SUe of the side portion 114_1S of the first part 114_1e of the first insulating pattern 114e may be disposed at a higher level than the lower portion 114_1SLe. The upper portion 114_1SUe of the side portion 114_1S of the first part 114_1e of the first insulating pattern 114e may be disposed at the same level as the second part 114_2e of the first insulating pattern 114e.

A thickness of the upper portion 114_1SUe of the side portion 114_1S of the first part 114_1e of the first insulating pattern 114e in the third direction D3 may be the same as a thickness of the second part 114_2e of the first insulating pattern 114e in the third direction D3. A thickness of the side portion 114_1Se of the first part 114_1e of the first insulating pattern 114e in the third direction D3 may be greater than a thickness of the second part 114_2e in the third direction D3. A thickness of the side portion 114_1Se of the first insulating pattern 114e in the third direction D3 may be defined as a sum of a thickness of the upper portion 114_1SUe in the third direction D3 and a thickness of the lower portion 114_1SLe in the third direction D3 of the side portion 114_1S of the first part 114_1e of the first insulating pattern 114e.

A sidewall 114_1SLSe and a bottom surface 114_1SLBe of the lower portion 114_1SLe of the side portion 114_1Se of the first part 114_1e of the first insulating pattern 114e may be in contact with the first substrate 111. The lower portion 114_1SLe of the side portion 114_1Se of the first part 114_1e of the first insulating pattern 114e may be disposed at a lower level than the top surface 111_T of the first substrate 111 and a bottom surface of the second part 114_2e of the first insulating pattern 114e.

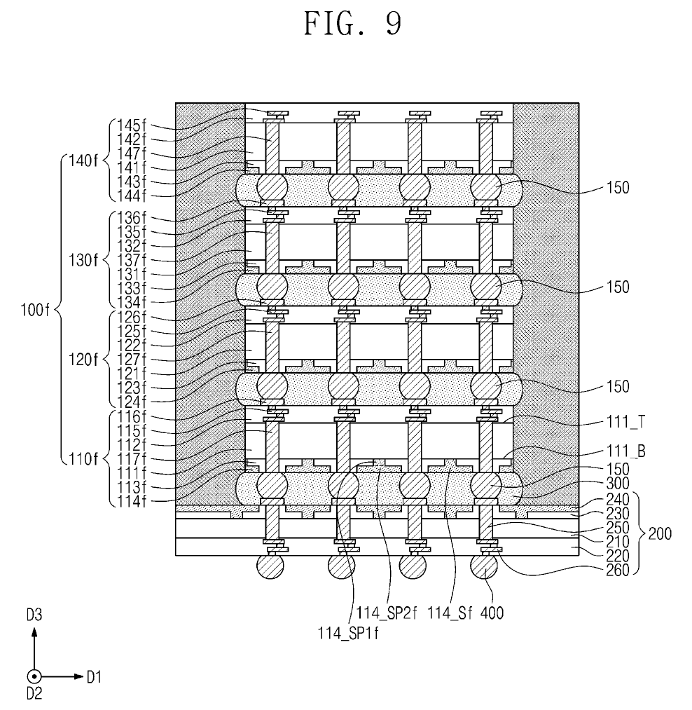

FIG. 9 is a diagram illustrating a semiconductor device according to some embodiments. Except for what will be described below, a semiconductor device according to FIG. 9 may be similar to the semiconductor device according to FIGS. 1A-1E.

Referring to FIG. 9, a first semiconductor chip 110f may include a first substrate 111f, a first lower insulating layer 113f, a first upper insulating layer 112f, a first insulating pattern 114f, a first line structure 115f, a first upper pad 116f and a penetration via 117f.

The first upper insulating layer 112f may be disposed on the top surface 111_Tf of the first substrate 111f. The first lower insulating layer 113f may be disposed on a bottom surface 111_Bf of the first substrate 111f. The top surface 111_Tf of the first substrate 111f may be a front surface of the semiconductor device, and the bottom surface 111_Bf may be a rear surface of the semiconductor device. The first upper insulating layer 112f may be disposed at a higher level than the first substrate 111f and the first lower insulating layer 113f.

The first insulating pattern 114f may be disposed at the same level as the first lower insulating layer 113f. The first side pattern portion 114_SP1f of the side portion 114_Sf of the first insulating pattern 114f may be disposed at a higher level than the second side pattern portion 114_SP2f. The first side pattern portion 114_SP1f of the side portion 114_Sf of the first insulating pattern 114f may be in contact with a bottom surface of the first substrate 111f. The second side pattern portion 114_SP2f of the side portion 114_Sf of the first insulating pattern 114f may be in contact with the lower adhesive layer 300. The first upper pad 116f may be electrically connected to the first line structure 115f. The first upper pad 116f may be disposed at a higher level than the first substrate 111f. The first line structure 115f may be disposed on the first upper insulating layer 112f. The first semiconductor chip 110f of FIG. 9 may have a form of turning the first semiconductor chip 110 of FIG. 1B upside down.

A second semiconductor chip 120f may include a second substrate 121f, a second lower insulating layer 123f, a second upper insulating layer 122f, a second insulating pattern 124f, a second line structure 125f, a second upper pad 126f and a penetration via 127f.

A third semiconductor chip 130f may include a third substrate 131f, a third lower insulating layer 133f, a third upper insulating layer 132f, a third insulating pattern 134f, a third line structure 135f, a third upper pad 136f and a penetration via 137f.

An upper semiconductor chip 140f may include a fourth substrate 141f, a fourth lower insulating layer 143f, a fourth upper insulating layer 142f, a fourth insulating pattern 144f, a fourth line structure 145f, a fourth upper pad 146f and a penetration via 147f. The second semiconductor chip 120f, the third semiconductor chip 130f and the upper semiconductor chip 140f may be similar to the first semiconductor chip 110f.

The second semiconductor chip 120f of FIG. 9 may have a form of turning the second semiconductor chip 120 of FIG. 1B upside down. The third semiconductor chip 130f of FIG. 9 may have a form of turning the third semiconductor chip 130 of FIG. 1B upside down.

The upper semiconductor chip 140 may have a similar form of turning the upper semiconductor chip 140 of FIG. 1B upside down. The penetration via 147f of the upper semiconductor chip 140f may be electrically connected to the interlayered connection terminal 150 and the fourth line structure 145f. The penetration via 147f of the upper semiconductor chip 140f may penetrate the fourth substrate 141f. The fourth upper insulating layer 142f may cover the fourth line structure 145f.

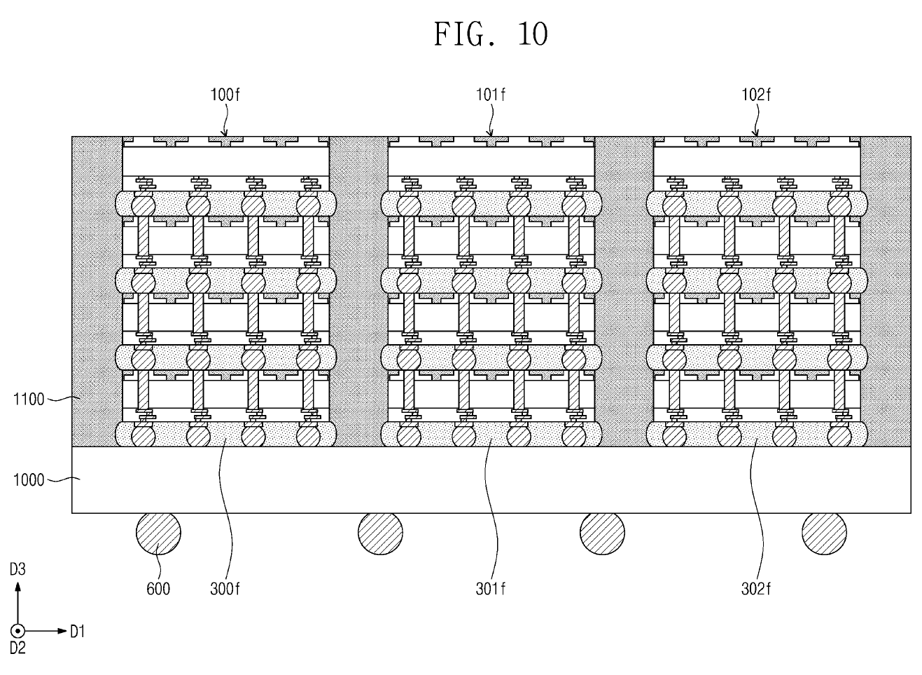

FIG. 10 is a diagram illustrating a semiconductor device according to some embodiments. Except for what will be described below, a semiconductor device according to FIG. 10 may be similar to the semiconductor device according to FIGS. 1A-1E.

Referring to FIG. 10, a package substrate 1000 may be provided. For example, the package substrate 1000 may be a printed circuit board (PCB). An external terminal 600 electrically connected to the package substrate 1000 may be provided. The external terminal 600 may include a conductive material. The external terminal 600 may include a solder ball or a bump electrically connected to an external device.

A first lower adhesive layer 300f, a second lower adhesive layer 301f and a third lower adhesive layer 302f may be disposed on the package substrate 1000. A first stack structure 100f may be disposed on the first lower adhesive layer 300f, a second stack structure 101f may be disposed on the second lower adhesive layer 301f and a third stack structure 102f may be disposed on the third lower adhesive layer 302f.

The first to third stack structures 100f, 101f and 102f may be arranged in the first direction D1. The first to third stack structures 100f, 101f and 102f may be spaced apart from each other in the first direction D1. The first to third stack structures 100f, 101f and 102f may be electrically connected to the package substrate 1000. The first to third stack structures 100f, 101f and 102f may be similar to the stack structure 100 of FIG. 1B.

An external molding layer 1100 covering the first to third stack structures 100f, 101f and 102f and the package substrate 1000 may be provided. The external molding layer 1100 may include an insulating material. For example, the third molding layer 1100 may include a polymer material.

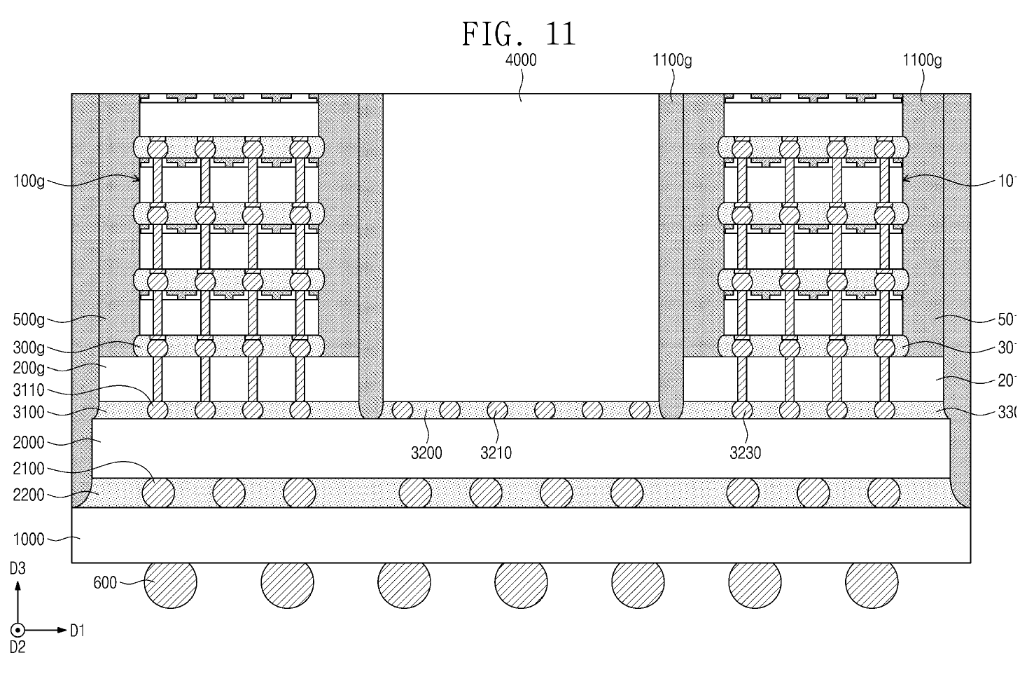

FIG. 11 is a diagram illustrating a semiconductor device according to some embodiments. Except for what will be described below, a semiconductor device according to FIG. 11 may be similar to the semiconductor device according to FIG. 10.

Referring to FIG. 11, an interposer 2000 overlapping the package substrate 1000 may be provided. The interposer 2000 may include a substrate, an insulating layer, a line and a via. The interposer 2000 may be electrically connected to the package substrate 1000. A first inner terminal 2100 and a first underfill 2200 surrounding the first inner terminal 2100 may be provided between the interposer 2000 and the package substrate 1000. The first inner terminal 2100 may include a conductive material.

The first inner terminal 2100 may be electrically connected to the package substrate 1000 and the interposer 2000. The first underfill 2200 may include an insulating material. For example, the first underfill 2200 may include a polymer material.

A second underfill 3100, a third underfill 3200 and a fourth underfill 3300 may be disposed on the interposer 2000. The second to fourth underfills 3100, 3200 and 3300 may include an insulating material. For example, the second to fourth underfills 3100, 3200 and 3300 may include a polymer material.

A second inner terminal 3110 may be disposed on the second underfill 3100. A third inner terminal 3210 may be disposed on the third underfill 3200. A fourth inner terminal 3310 may be disposed on the fourth underfill 3300.

A first base chip 200g may be disposed on the second underfill 3100. A first lower adhesive layer 300g may be disposed on the first base chip 200g. The first stack structure 100g may be disposed on the first lower adhesive layer 300g. A first molding layer 500g covering the first base chip 200g, the first lower adhesive layer 300g and the first stack structure 100g may be provided. The second inner terminal 3110 may be electrically connected to the first base chip 200g and the interposer 2000.

A second base chip 201g may be disposed on the fourth underfill 3300. A second lower adhesive layer 301g may be disposed on the second base chip 201g. A first stack structure 101g may be disposed on the second lower adhesive layer 301g. A second molding layer 501g covering the second base chip 201g, the second lower adhesive layer 301g and the second stack structure 101g may be provided. The fourth inner terminal 3310 may be electrically connected to the second base chip 201g and the interposer 2000.

A logic chip 4000 may be disposed on the third underfill 3200. For example, the logic chip 4000 may include a central processing unit (CPU), a graphics processing unit (GPU) or an application specific integrated circuit (ASIC). The logic chip 4000 may transmit a signal to the first stack structure 100g or the second stack structure 101g, or may receive a signal from the first stack structure 100g or the second stack structure 101g. The third inner terminal 3210 may be electrically connected to the logic chip 4000 and the interposer 2000.

The logic chip 4000 may be disposed between the first stack structure 100g and the second stack structure 101g. The first stack structure 100g, the second stack structure 101g and the logic chip 4000 may be arranged in the first direction D1. The first stack structure 100g, the second stack structure 101g and the logic chip 4000 may be spaced apart from each other in the first direction D1.

An external molding layer 1100g covering the first underfill 2200, the interposer 2000, the second underfill 3100, the third underfill 3200, the fourth underfill 3300, the first base chip 200g, the second base chip 201g, the logic chip 4000, the first molding layer 500g and the second molding layer 501g may be provided.

The external molding layer 1100g may include an insulating material. For example, the external molding layer 1100g may include a polymer material.

Since a semiconductor device according to embodiments of the present disclosure includes insulating patterns including different insulating material on insulating layers, a warpage phenomenon may be reduced. Accordingly, stability of the semiconductor device may be improved.

In a semiconductor device according to embodiments of the present disclosure, since insulating layers include an oxide, and insulating patterns include a nitride having a relatively high stress, a warpage phenomenon may be reduced.

In a semiconductor device according to embodiments of the present disclosure, since insulating patterns further include a first side pattern portion having a narrower width than a second side pattern portion, a warpage phenomenon may be reduced.

A method for manufacturing a semiconductor device according to embodiments of the present disclosure may include patterning a preliminary insulating layer. Accordingly, an insulating pattern may include first and second side pattern portions. Accordingly, a warpage phenomenon in a hot pressing process may be reduced.

The first side pattern portion may be formed along a pattern of a patterned preliminary insulating layer in the method for manufacturing a semiconductor device according to embodiments of the present disclosure. Accordingly, a form of the first side pattern portion may be differently formed along a direction of the warpage. The warpage phenomenon may be reduced by making the form of the first side pattern portion different along the direction of the warpage.

In a semiconductor device according to embodiments of the present disclosure, a first side pattern portion may penetrate a top surface of a substrate to be formed. Accordingly, a thickness of the first side pattern portion may be relatively increased. Accordingly, a warpage phenomenon may be effectively reduced.

In a semiconductor device according to embodiments of the present disclosure, an insulating pattern may include a first part and a second part including different insulating materials. According to a warpage direction of the semiconductor device, the first part and the second part of the first insulating pattern may be patterned in different forms. Accordingly, a warpage phenomenon may be effectively reduced.

Although the embodiments of the present disclosure have been described, it is understood that the present disclosure should not be limited to these embodiments but various changes and modifications can be made by one ordinary skilled in the art within the spirit and scope of the present disclosure as hereinafter claimed. Therefore, it should be understood that the embodiments described above are exemplary in all respects and are not intended to be limiting.

What is claimed is:

1. A semiconductor device comprising:
a substrate;
a first via penetrating the substrate;
a second via penetrating the substrate; and
an insulating pattern surrounding the first via and the second via,
wherein the insulating pattern comprises a first portion between the first via and the second via,
wherein the first portion comprises a first pattern portion and a second pattern portion overlapping the first pattern portion, and
wherein a width of the first pattern portion is smaller than a width of the second pattern portion.

2. The semiconductor device of claim 1, further comprising an insulating layer surrounding the first via and the second via,
wherein the first portion is spaced apart from the first via and the second via, and
wherein the insulating layer comprises a first part between the first pattern portion and the first via, and a second part between the second pattern portion and the first via.

3. The semiconductor device of claim 2, wherein the insulating pattern and the insulating layer comprise different insulating materials.

4. The semiconductor device of claim 2, wherein a surface of the second pattern portion is connected to a wall of the first pattern portion and a wall of the second pattern portion.

5. The semiconductor device of claim 2, wherein the insulating layer is in contact with a surface of the substrate, a wall of the first via, a wall of the first pattern portion and a wall of the second pattern portion.

6. The semiconductor device of claim 2, wherein a surface of the second pattern portion and a surface of the insulating layer are coplanar with each other.

7. The semiconductor device of claim 2, wherein the insulating layer is in contact with a surface of the second pattern portion.

8. The semiconductor device of claim 1, wherein the first via, the second via, and the first portion are spaced apart from each other in a first direction,
wherein the semiconductor device further comprises a third via spaced apart from the first via and the second via in a second direction crossing the first direction,
wherein the insulating pattern further comprises a planarization portion between the first via and the third via,
wherein the planarization portion is spaced apart from the substrate, and
wherein the first portion contacts the substrate.

9. The semiconductor device of claim 8, wherein a first surface and a second surface of the planarization portion are flat.

10. The semiconductor device of claim 1, wherein the first pattern portion penetrates a surface of the substrate, and
wherein a surface of the first pattern portion is spaced apart from the surface of the substrate.

11. A semiconductor device comprising:
a substrate;
a first via penetrating the substrate;
a second via penetrating the substrate; and
an insulating pattern surrounding the first via and the second via,
wherein the insulating pattern comprises a first portion between the first via and the second via,
wherein the first portion comprises a first pattern portion and a second pattern portion overlapping the first pattern portion,
wherein the second pattern portion comprises a first part, a second part and a third part,
wherein the second part of the second pattern portion overlaps the first pattern portion,
wherein the first part and the third part of the second pattern portion are spaced apart from each other,
wherein the second part of the second pattern portion is between the first part and the third part, and
wherein a level of a surface of the first pattern portion is lower than a level of a surface of the first part of the second pattern portion and a level of a surface of the third part of the second pattern portion.

12. The semiconductor device of claim 11, wherein the first part and the third part of the second pattern portion comprise same first insulating material,
wherein the second part of the second pattern portion comprises a second insulating material different from the first insulating material, and
wherein the first pattern portion comprises the second insulating material.

13. The semiconductor device of claim 12, wherein the first insulating material comprises a nitride, and
wherein the second insulating material comprises an oxide.

14. The semiconductor device of claim 11, further comprising:
an insulating layer between the first portion and the first via, and including an insulating material different from the insulating pattern,
wherein the insulating layer is in contact with a surface of the substrate.

15. The semiconductor device of claim 14, wherein a surface of the first part of the second pattern portion, a surface of the second part of the second pattern portion, a surface of the third part of the second pattern portion and a surface of the insulating layer are coplanar with each other.

16. The semiconductor device of claim 11, wherein a wall of the first pattern portion is in contact with the substrate.

17. A semiconductor device comprising:
a substrate;
a first via penetrating the substrate;
a second via penetrating the substrate;
an insulating pattern on a surface of the substrate, and surrounding the first via; and
an insulating layer on the substrate,
wherein the insulating pattern comprises a first portion between the first via and the second via,
wherein the first portion comprises a first pattern portion and a second pattern portion overlapping the first pattern portion, and
wherein the first pattern portion protrudes from the second pattern portion.

18. The semiconductor device of claim 17, wherein the second pattern portion comprises a first wall and a second wall opposed to each other,
wherein the first pattern portion is spaced apart from the first wall and the second wall of the second pattern portion.

19. The semiconductor device of claim 17, wherein the first via, the second via and the first portion are spaced apart from each other in a first direction,
wherein the semiconductor device further comprises a corner portion connected to the first portion, and
wherein the corner portion and the first via, and the corner portion and the second via are spaced apart from each other in a second direction crossing the first direction.

20. The semiconductor device of claim 19, wherein the corner portion comprises a corner pattern portion connected to the first pattern portion, and
wherein the corner pattern portion has a form of a cross.
